(19) United States
(12) Patent Application Publication
(10) Pub. No.: US 2026/0040577 A1
(43) Pub. Date: Feb. 5, 2026

(54) MICROELECTRONIC DEVICES, AND RELATED METHODS OF FORMING MICROELECTRONIC DEVICES

(71) Applicant: Micron Technology, Inc.,, Boise, ID (US)

(72) Inventors: Paolo Fantini, Vimercate (IT); Christophe Vincent Antoine Laurent, Agrate Brianza, MB (IT); Andrea Martinelli, Bergamo, BG (IT); Anna Maria Conti, Milano (IT); Efrem Bolandrina, Fiorano Al Serio, BG (IT); Paolo Tessariol, Arcore (IT)

(21) Appl. No.: 19/254,725

(22) Filed: Jun. 30, 2025

Related U.S. Application Data
(60) Provisional application No. 63/677,994, filed on Jul. 31, 2024.

(51) Int. Cl. H10B 63/00

(52) U.S. Cl. CPC H10B 63/84; H10B 63/30

(57) ABSTRACT

A microelectronic device includes a stack structure including tiers respectively including a local word line structure, each local word line including a backbone member and extensions, the extensions being coupled to memory cells of an array region and thin film transistors at vertical positions of the tiers and respectively including a first source/drain region coupled to a backbone member of a local word line on a horizontal side of the backbone member opposite the extensions of the respective local word line, a second source/drain region coupled to a global word line, and a channel region horizontally extending from the first source/drain region to the second source/drain region.

### CROSS-REFERENCE TO RELATED APPLICATION

This application claims the benefit under 35 U.S.C. § 119 (e) of U.S. Provisional Patent Application Ser. No. 63/677,994, filed Jul. 31, 2024, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device.

### BRIEF DESCRIPTION OF THE DRAWINGS

To easily identify the discussion of any particular element or act, the leading digit or digits in a reference number refer to the figure number in which that element is first introduced.

FIG. 1 shows a schematic, top-down view of a portion of a microelectronic device, according to one or more embodiments of the disclosure;

FIG. 2 shows an electrical schematic of a microelectronic device, according to one or more embodiments of the disclosure;

FIG. 3 shows an exploded, perspective view of microelectronic device, according to one or more embodiments of the disclosure;

FIG. 4 through FIG. 15B show various simplified views of a microelectronic device at different processing stages of a method of forming the microelectronic device, according to one or more embodiments of the disclosure;

FIG. 16 shows a schematic diagram of a multi-gate thin film transistor;

FIG. 17 shows a schematic diagram of a multi-gate thin film transistor; and

FIG. 18 is a block diagram of an electronic system, in accordance with embodiments of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

The materials described herein may be formed by conventional techniques including, but not limited to, spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate to a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for case of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially-sacrificial” material means and includes a sacrificial material from which only one or more portions is or are removed prior to completion of the fabrication process. A “wholly-sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InxO), tin oxide (SnxO), titanium oxide (TixO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

As used herein, the term “dog-bone shape” and derivative terms may refer to a shape including a central elongated portion that is elongated in a first direction, and two wide end portions defined at opposite horizontal ends of the central elongated portion. In particular, each of the two wide end portions is defined at a respective end of the central elongated portion in the first direction (i.e., the direction in which the central elongated portion is elongated). Additionally, the two wide end portions are wider than the central elongated portion in a second direction orthogonal to the first direction. Furthermore, each of the central elongated portion and the two wide end portions are at least substantially symmetrical about a central longitudinal axis extending in the first direction.

Furthermore, as used herein, the term “dog-bone opening” may refer to an opening having a dog-bone shaped cross-section within the XY-plane as depicted in the figures.

As used herein, the term “comb structure” may refer to structure having a backbone member extending longitudinally in a first horizontal direction and multiple extensions extending longitudinally from one lateral horizontal side of the backbone member in a second horizontal direction orthogonal to first horizontal direction.

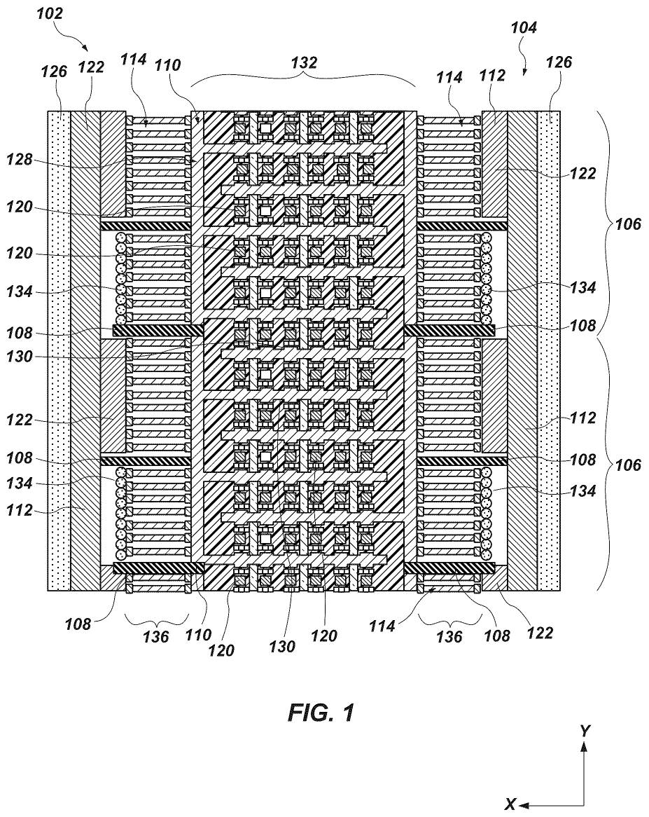

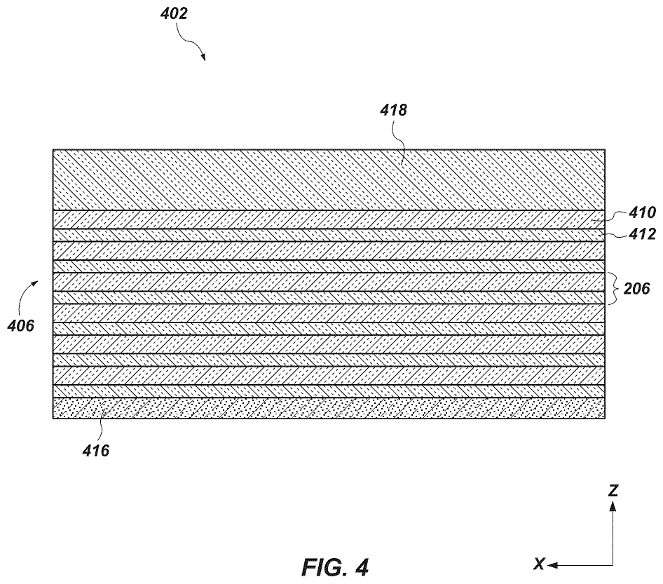

FIG. 1 shows a schematic, top-down view of a portion of a microelectronic device 102 according to one or more embodiments of the disclosure. The microelectronic device 102 may include at least one deck 104 (e.g., stack structure) including a vertically (e.g., in the Z-direction (FIG. 4)) alternating sequence of insulative material and conductive material arranged in tiers. Each of the tiers may individually include a level of the insulative material directly vertically neighboring (e.g., adjacent) a level of the conductive material. FIG. 1 shows a top-down view of the microelectronic device 102 at a vertical cross-section that is coplanar with a conductive material of a given tier. The at least one deck 104 and its formation are described in greater detail below in regard to FIG. 4 through FIG. 17.

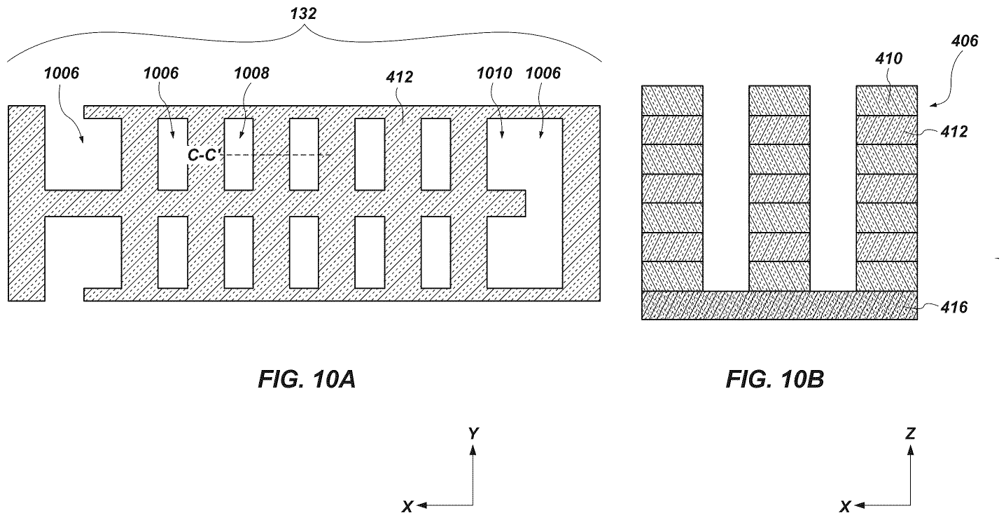

The deck 104 may be divided into sub-tiles 106 at least partially separated from one another by insulative structures 108. The insulative structures 108 may include material, which is unremoved by a so-called “replacement gate” or “gate last” process during formation of global word lines 112 and local word lines 110 of the sub-tiles 106. In particular, the insulative structures 108 may include maintained vertical stacks of insulative material and other insulative material. Local word lines 110 of neighboring sub-tiles 106 in the Y-direction may be separated from one another by one or more of the insulative structures 108. Formation of the global word lines 112 and local word lines 110 and the so-called “replacement gate” or “gate last” processes are described in greater detail below in regard to FIG. 10A through FIG. 15B.

Groups of thin film transistors 114 and a stack of global word lines 112 may be positioned within a vertical extent of the deck 104 (and, hence, of the sub-tiles 106 thereof). The sub-tiles 106 may respectively include local word lines 110 formed by conductive material of the tiers of the deck 104 and arrays of memory cells 120 operatively associated with the local word lines 110 and within array regions 132 of the sub-tiles 106. Each of the local word lines 110 may have a comb structure including a backbone member 128 extending in the Y-direction and extensions 130 (e.g., teeth members) extending from the backbone member 128 in the X-direction.

As noted above, the arrays of memory cells 120 (e.g., non-volatile memory cells) of the sub-tiles 106 may be positioned within array regions 132 of the sub-tiles 106 horizontally offset (e.g., in the X-direction) from the thin film transistors 114. For example, the sub-tiles 106 may individually include an array (e.g., a 3D cross-point array) of memory cells 120. The memory cells 120 of the array may, for example, comprise resistance variable memory cells, such as resistive random access memory (RRAM) cells, conductive bridge random access memory (conductive bridge RAM) cells, magnetic random access memory (MRAM) cells, phase change material (PCM) memory cells, phase change random access memory (PCRAM) cells, spin-torque-transfer random access memory (STTRAM) cells, oxygen vacancy-based memory cells, or programmable conductor memory cells. In some embodiments, the memory cells 120 of the sub-tiles 106 are formed at intersections of local word lines 110 and bit lines.

Referring still to FIG. 1, within the array region 132 of a given sub-tile 106, the sub-tile 106 may include a first local word line 110 (e.g., left local word line) having extensions 130 horizontally extending from a backbone member 128 in a first direction and a second local word line 110 (e.g., a right local word line) having extensions 130 horizontally extending from a backbone member 128 in a second, opposite direction. As a result, except for one extension 130 of each of the first and second local word lines 110, each other extension 130 of the first and second local word lines 110 may be horizontally nested between extensions 130 of the other of the first or second local word lines 110. Accordingly, as depicted in FIG. 1, a serpentine path may be defined between the first local word line 110 (e.g., left local word line) and the second local word line 110 (e.g., a right local word line). Furthermore, the memory cells 120 of the given sub-tile 106 are formed within the serpentine path between extensions 130 of the first and second local word lines 110.

The thin film transistors 114 may be formed in tier and within thin film transistor regions 136 horizontally neighboring and on opposing horizontal sides of the array region 132 of a given sub-tile 106 in the X-direction. The thin film transistors 114 may be coupled to and extend horizontally away from backbone members 128 of the local word lines 110 on both sides of the array region 132 and in the X-direction. For instance, the array region 132 may be horizontally in-between sets of thin film transistors 114 coupled to the local word lines 110 within the array region 132 and extending horizontally away from local word lines 110 in an opposing X-direction.

For each local word line 110 of a given sub-tile 106, a first group of thin film transistors 114 may horizontally extend between the local word line 110 and a contact structure 122 of the stack of global word lines 112 in the X-direction. For example, the first group of thin film transistors 114 may extend from a backbone member 128 of a given local word line 110 to the contact structure 122, which is connected to a global word line 112.

Additionally, for each local word line 110 of a given sub-tile 106, a second group of thin film transistors 114 may horizontally extend between the local word line 110 and a pillar structure 134, instead of a contact structure 122 coupled to a global word line 112. For example, the second group of thin film transistors 114 may extend from the backbone member 128 of the local word line 110 to the pillar structure 134.

In view of the foregoing, the thin film transistors 114 may horizontally extend (e.g., extend longitudinally) in a direction opposite to the direction in which the extensions 130 of the local word lines 110 extend (e.g., extend longitudinally). Furthermore, longitudinal axes of the thin film transistors 114 may be at least substantially parallel to or colinear with longitudinal axes of the extensions 130 of the local word lines 110.

The pillar structure 134 may provide a connection and/or signal path to an earth node (e.g., electrical ground). Furthermore, the pillar structure 134 may couple (e.g., short) all of the thin film transistors 114 (e.g., all of the source structures of the thin film transistors 114) of the second group of thin film transistors 114 within a given tier of the deck 104 together. Moreover, the pillar structure 134 may short thin film transistors 114 of second groups from differing and vertically neighboring tiers of the deck 104 together. For example, the pillar structure 134 may short thin film transistors 114 that are from differing tiers of the deck 104, but are horizontally aligned with (e.g., directly below or above) the second group of thin film transistors 114 together. Put another way, for a given sub-tile 106, each tier of the deck 104 may include a second group of thin film transistors 114 coupled to a respective local word line 110 of the respective tier, and the second groups of thin film transistors 114 of the given sub-tile 106 may be horizontally aligned and all shorted together by the pillar structure 134.

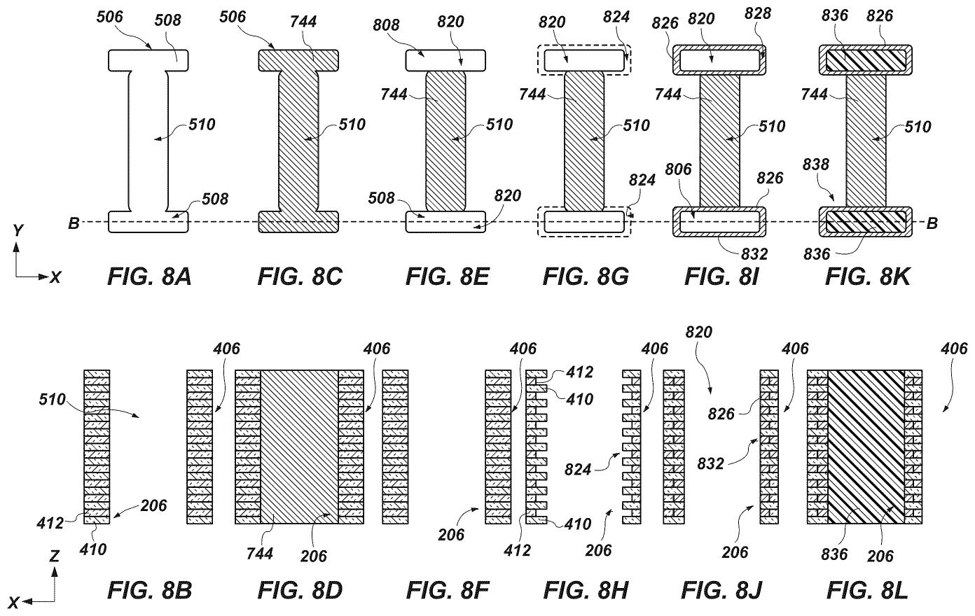

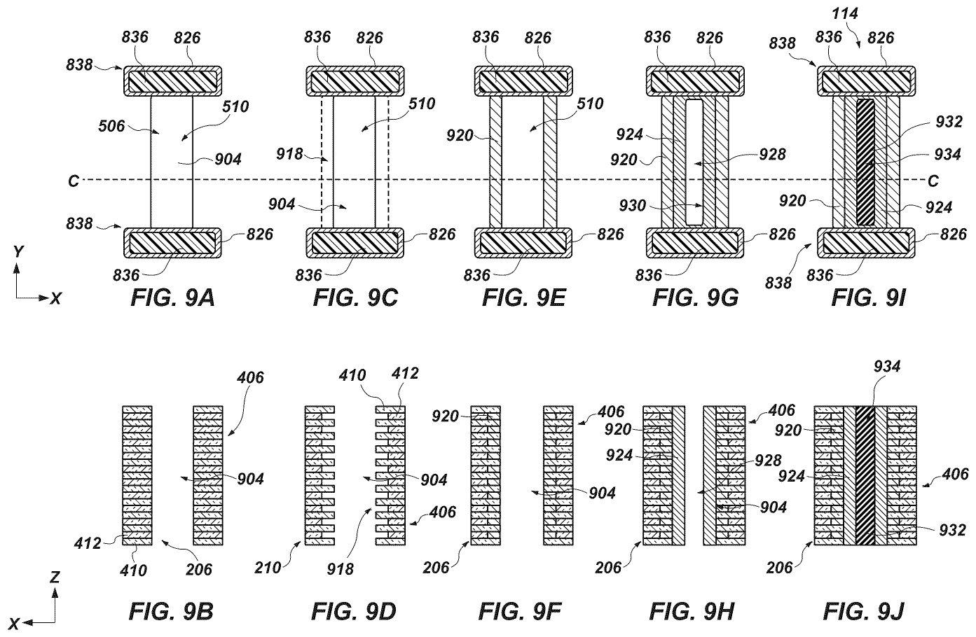

The thin film transistors 114 may serve as select transistors for the sub-tiles 106 (e.g., transistors for controlling read and write operations). During use and operation of the microelectronic device 102, the thin film transistors 114 may facilitate desired transmission of signals from the global word lines 112 to the local word lines 110 (and, hence, the memory cells 120) of the sub-tiles 106. The thin film transistors 114 may enable precise addressing of specific memory cells 120 (e.g., pillars) of the sub-tiles 106 during data retrieval and programming. Furthermore, the thin film transistors 114 may serve as local word line 110 decoders (e.g., in tier decoders). For instance, during use and operation of the microelectronic device 102, the thin film transistors 114 may facilitate activation of individual local word lines 110 based on binary addresses. When an address is provided, the thin film transistors 114 enable selection of a specific local word line 110 and access to associated data within the memory cells 120 accessible via the specific local word line 110. The structure and formation of the thin film transistors 114 are described in greater detail below in regard to FIG. 8A through FIG. 9J.

The deck 104 may further include a so-called “staircase” (or “stair step”) structure 126 at edges (e.g., horizontal end) of the tiers of the deck 104 (e.g., within staircase structure regions of the microelectronic device 102). The staircase structures 126 may respectively include individual “steps” defining contact regions for the global word lines 112. Contact structures may land on treads of the steps of the staircase structures 126 to facilitate electrical communication between the global word lines 112 and control logic circuitry vertically positioned above and/or below the deck 104. Furthermore, the stack of global word lines 112 may be located proximate the edges (e.g., opposing edges) of the deck and at least partially within horizontal areas of the staircase structure regions of the microelectronic device 102. The global word lines 112 may respectively be connected to the first group of thin film transistors 114 positioned within the vertical extent of the deck 104 through the contact structures 122. Accordingly, the thin film transistors 114 may facilitate selective electrical communication between the global word lines 112 and the local word lines 110.

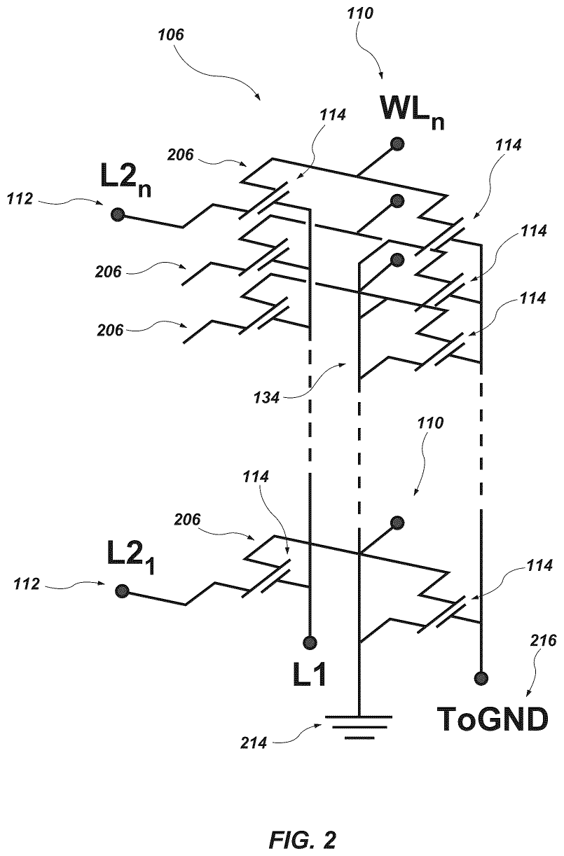

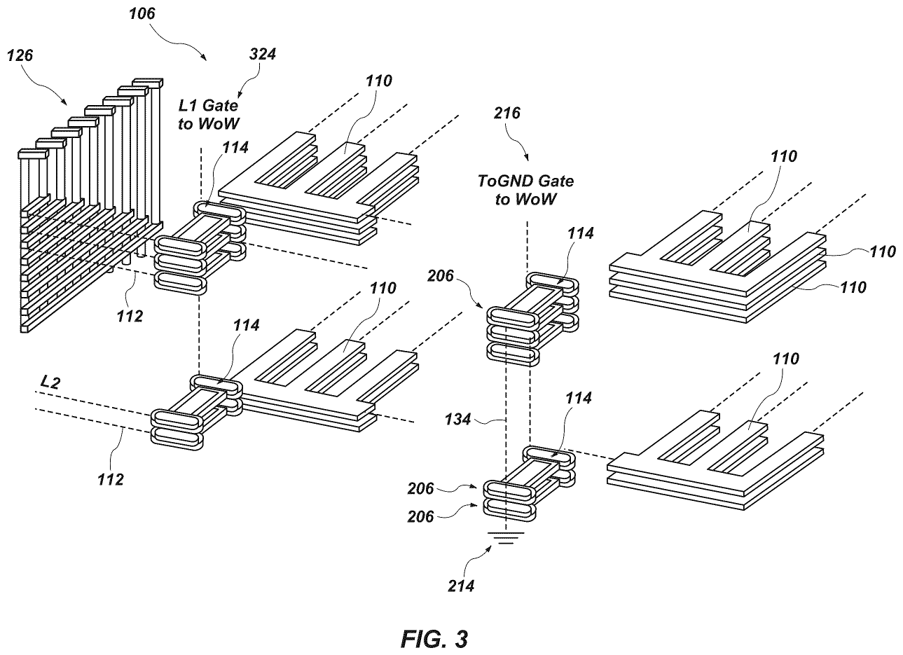

FIG. 2 is an electrical schematic representation of a sub-tile 106 of the deck 104 of FIG. 1. FIG. 3 is an exploded view of a portion of a sub-tile 106 of the deck 104 of FIG. 1. Some elements and structures of the portion of the sub-tile 106 shown in FIG. 3 are removed to better depict details of the portion of the sub-tile 106.

Referring to FIG. 2 and FIG. 3 together, multiple tiers 206 of the sub-tile 106 are represented, and each tier 206 includes respective thin film transistors 114 from the first group and thin film transistors 114 from the second group. As noted above, each of the thin film transistors 114 from the first group of the thin film transistors 114 may be operably coupled to local word lines 110 of an array region 132 (FIG. 1) and a global word line 112 (L2ₙ) by way of a contact structure 122 (FIG. 1). Furthermore, as noted above, each of the thin film transistors 114 from the second group of the thin film transistors 114 may be operably coupled to the local word lines 110 of the array region 132 (FIG. 1) and the pillar structure 134, which provides a connection and/or signal path to an earth node 214 (e.g., electrical ground or zero voltage). Additionally, the gates of vertically stacked thin film transistors 114 of the second group may be coupled together vertically and may be connected to a ground node 216. The ground node 216 may provide a reference voltage (e.g., a reference bias).

Referring to FIG. 1, FIG. 2, and FIG. 3, the comb structure of the local word lines 110 and the first and second groups of thin film transistors 114 (i.e., decoders) enables the microelectronic device 102 (FIG. 1) to employ double polarity bias on the local word lines 110. In particular, the array region 132 may include memory cells 120 configured as resistance variable memory cells (e.g., RRAM cells, a CBRAM cells, an MRAM cells, a PCM memory cells, a PCRAM cells, a STTRAM cells, oxygen vacancy-based memory cells, programmable conductor memory cells) respectively including a storage element structure formed of and including a resistance variable material. As used herein, the term “resistance variable material” means and includes a material formulated to be switched from one resistance state to another resistance state upon application of at least one physical signal (e.g., at least one of heat, voltage, current, or other physical phenomena) thereto. The resistance variable material of storage element structures of the memory cells 120 may, for example, be formed of an active switching material (e.g., a transition metal oxide (TMO) material, a dielectric metal oxide, a chalcogenide material), a metal ion source material, or an oxygen-gettering material. In order to avoid transient currents during write operations, a double polarity biasing process can be utilized. For example, when selecting a memory cell 120, selected memory cells 120 may receive a positive voltage bias from their respective local word line 110, and unselected memory cells 120 may receive a negative voltage bias (opposite polarity) from their respective local word line 110. The foregoing process ensures that only intended memory cells 120 experience necessary current for desired resistance changes.

In view of the foregoing, having the gates of the thin film transistors 114 of the second group of thin film transistors 114 coupled to a ground node 216 (i.e., a reference voltage) enables unselected local word lines 110 to be shorted to the reference voltage for biasing the local word lines 110 with the reference voltage. The pillar structure 134 enables source structures of the thin film transistors 114 of the second group of thin film transistors 114 to be shorted to a zero voltage (0v).

In some embodiments, the sub-tiles 106 include sockets 324 coupled to the gates of a given stack of thin film transistors 114 from either or both of the first group and the second group of thin film transistors 114 and located on a top and/or a bottom of the sub-tiles 106 in the Z-direction. The sockets 324 enable connections to additional circuitry that may be bonded to the top and/or the bottom of the microelectronic device 102 by way of wafer-on-wafer bonding.

Referring to FIG. 1, FIG. 2, and FIG. 3, in some embodiments, the sub-tiles 106 do not include the second group of thin film transistors 114 having source structures coupled to a pillar structure 134 providing a connection to an earth node 214 and gates being connected to a ground node 216 (e.g., reference voltage).

FIG. 4 through FIG. 15B are various views (described in more detail below) showing a method of forming a microelectronic device (e.g., microelectronic device 102 (FIG. 1)), in accordance with embodiments of the disclosure. FIG. 4 is a simplified partial vertical cross-sectional view of a microelectronic device structure 402, in accordance with embodiments of the disclosure. The microelectronic device structure 402 may include a stack structure 406 (to become the deck 104 (FIG. 1)) including a vertically (e.g., in the Z-direction) alternating sequence of insulative material 410 and other insulative material 412 arranged in tiers 206. Each of the tiers 206 may individually include a level of the insulative material 410 vertically neighboring (e.g., adjacent) a level of the other insulative material 412. The levels of insulative material 410 of the stack structure 406 may also be referred to herein as “insulative structures,” and the levels of other insulative material 412 of the stack structure 406 may also be referred to herein as “other insulative structures.”

In some embodiments, a number (e.g., quantity) of tiers 206 of the stack structure 406 is within a range of from 32 of the tiers 206 to 256 of the tiers 206. In some embodiments, the stack structure 406 includes 128 of the tiers 206. However, the disclosure is not so limited, and the stack structure 406 may include a different number of the tiers 206. In addition, in some embodiments, the stack structure 406 vertically overlies (e.g., in the Z-direction) a source structure 416 and includes multiple (e.g., two, more than two) preliminary deck structures vertically stacked relative to one another and individually including a group (e.g., sub-stack) of the tiers 206 of the insulative material 410 and the other insulative material 412. In some such embodiments, a first preliminary deck structure is separated from a second deck structure by an interdeck region. For example, the stack structure 406 may have a dual deck configuration.

The levels of the insulative material 410 may individually be formed of and include, for example, at least one dielectric material, such as one or more of an oxide material (e.g., silicon dioxide (SiO₂)), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃). In some embodiments, the insulative material 410 is formed of and includes silicon dioxide.

The levels of the other insulative material 412 may individually be formed of and include an insulative material that is different than, and exhibits an etch selectivity with respect to, the insulative material 410. In some embodiments, the other insulative material 412 are formed of and include a dielectric nitride material (e.g., silicon nitride (Si₃N₄)) or a dielectric oxynitride material (e.g., silicon oxynitride). In some embodiments, the other insulative material 412 is formed of and includes silicon nitride.

The stack structure 406 may be formed over the source structure 416 (e.g., a source material, a source plate). The source structure 416 may be formed of and include, for example, one or more of conductive material and a doped semiconductor material (e.g., semiconductor material doped with one or more P-type conductivity materials, such as polysilicon doped with one or more of boron, aluminum, and gallium; semiconductor material doped one or more N-type conductivity materials, such as one or more of arsenic, phosphorous, antimony, and bismuth). Although FIG. 4 has been described and illustrated as including the stack structure 406 directly over (e.g., on) the source structure 416, the disclosure is not so limited. In other embodiments, one or more features (e.g., materials, structures) are vertically interposed between the stack structure 406 and the source structure 416.

A dielectric material 418 may be located over an uppermost one of the tiers 206. The dielectric material 418 may be formed of and include insulative material, such as, for example, one or more of phosphosilicate glass (PSG), borosilicate glass (BSG), fluorosilicate glass (FSG), borophosphosilicate glass (BPSG), and silicon dioxide. In some embodiments, the dielectric material 418 includes the same material composition as the insulative material 410. In some embodiments, the dielectric material 418 is formed of and includes silicon dioxide.

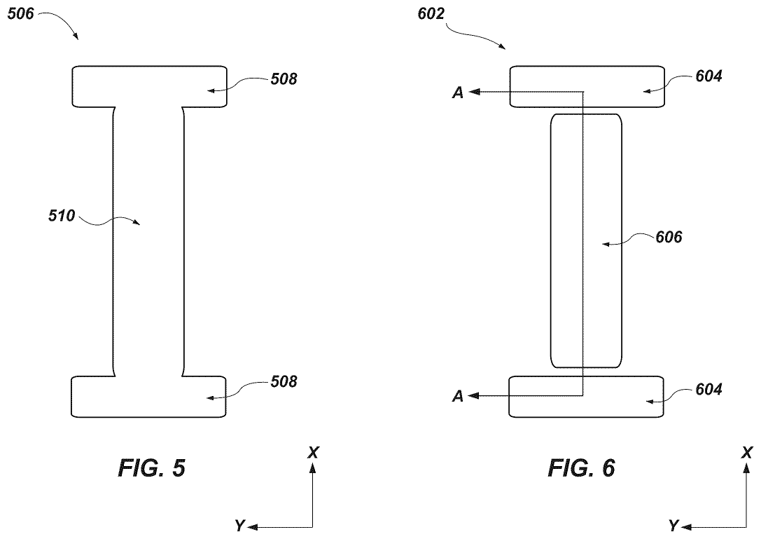

FIG. 5 is a schematic, top-down view of a dog-bone opening 506 that may be utilized to form the in-tier thin film transistors 114 briefly described above in regard to FIG. 1. Referring to FIG. 1, FIG. 4, and FIG. 5 together, during formation of the microelectronic device 102, within horizontal areas of the thin film transistor regions 136 of in-tier control circuitry regions of the sub-tiles 106, dog-bone openings 506 may be formed within tiers 206 of the stack structure 406. The dog-bone openings 506 may vertically extend (e.g., in the Z-direction) through the insulative material 410 and the other insulative material 412 of the tiers 206 of the stack structure 406 within the thin film transistor regions 136 on opposing horizontal sides the array regions 132 of the sub-tiles 106 in the X-direction. For instance, in some embodiments, the dog-bone openings 506 extend entirely through the stack structure 406 in the Z-direction to the source structure 416.

The dog-bone openings 506 may have a general dog-bone shape within the XY-plane. In particular, within the XY-plane, an individual dog-bone opening 506 may include two wide end portions 508 defined on opposing ends of a central elongated portion 510 in the X-direction. The central elongated portion 510 may be elongated in the X-direction. The wide end portions 508 may each be wider than the central elongated portion 510 in the Y-direction. As is discussed in greater detail below, source and/or drain structures of the thin film transistors 114 are formed within the wide end portions 508 of the dog-bone openings 506.

The dog-bone openings 506 may be formed utilizing a mask structure (e.g., a patterned photoresist material, a patterned hard mask material) with a pattern of the dog-bone openings 506 defined therein. For example, the pattern may be defined in a photoresist material (e.g., through selective light exposure using a reticle followed by development) to form a patterned photoresist material, and then the patterned photoresist material may be used to etch the pattern through the stack structure 406 to define the dog-bone openings 506 in the thin film transistor regions 136 of the sub-tiles 106. For instance, the dog-bone openings 506 may be formed via one or more directional etches (i.e., anisotropic etches). Additionally, when the stack structure 406 of the microelectronic device structure 402 includes multiple preliminary deck structures stacked on top of each other in the Z-direction, the dog-bone openings 506 may be formed in each preliminary deck structure, respectively. For example, upon formation of a first preliminary deck structure (e.g., lowermost preliminary deck structure), the dog-bone openings 506 are formed in the first preliminary deck structure and filled (described below). Subsequently, a second preliminary deck structure is formed above the first preliminary deck structure, and more of the dog-bone openings 506 are formed in the second preliminary deck structure and filled. Any further preliminary deck structures formed above of the second preliminary deck structure may have further of the dog-bone openings 506 formed therein and filled in the same manner. In other words, the dog-bone openings 506 may be formed and then filled on a deck-by-deck basis.

After forming the dog-bone openings 506, the dog-bone openings 506 may be filled with sacrificial material. For instance, the sacrificial material may be deposited within the dog-bone openings 506 through a spin-on coating process. In some embodiments, the sacrificial material is a spin-on carbon. In other embodiments, the sacrificial material is deposited through any of the other deposition methods described herein. In some embodiments, some dog-bone openings 506 are filled with a first sacrificial material and other dog-bone openings 506 are filled with a second sacrificial material. Filling the dog-bone openings 506 with the sacrificial material may form pillars (i.e., pillars of the sacrificial material) within the openings.

FIG. 6 is a schematic, top-down view of a group of openings 602 that may be utilized to form a merged dog-bone opening, which, in turn, can be utilized to form the in-tier thin film transistors 114 briefly described above in regard to FIG. 1. The groups of openings 602 may be formed in the same manner as the dog-bone openings 506 (FIG. 5) and within the same horizontal areas of the sub-tiles 106 described above in regard to FIG. 5.

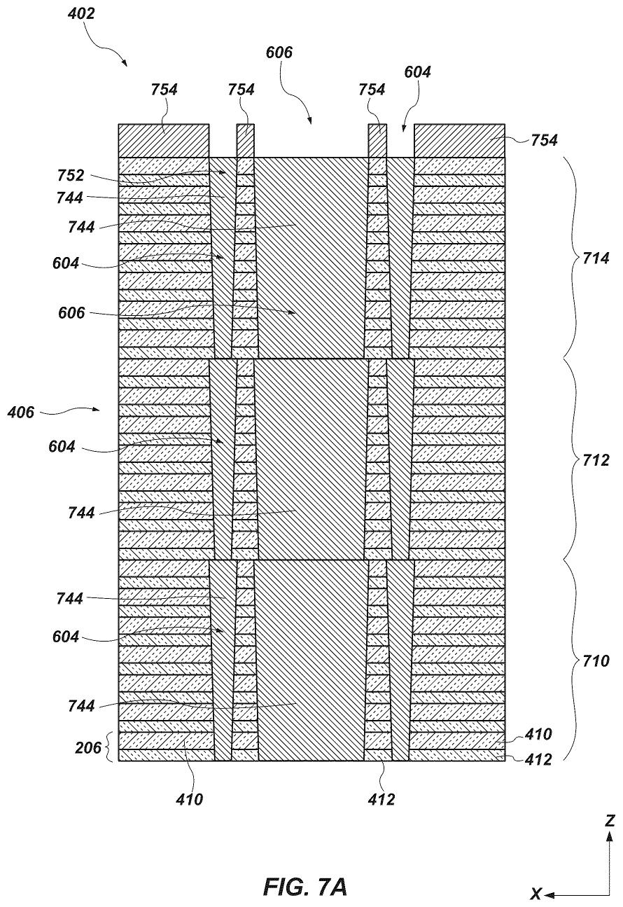

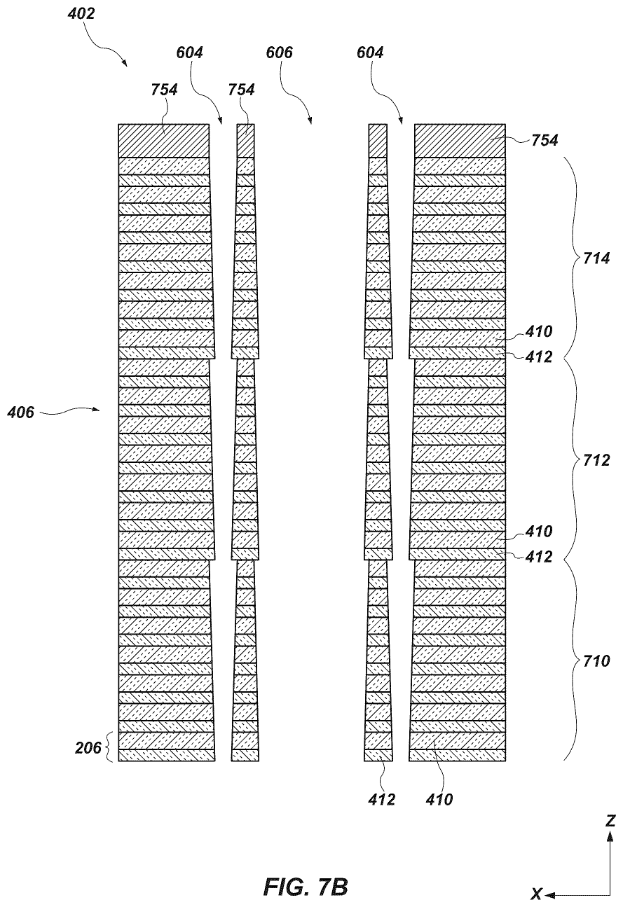

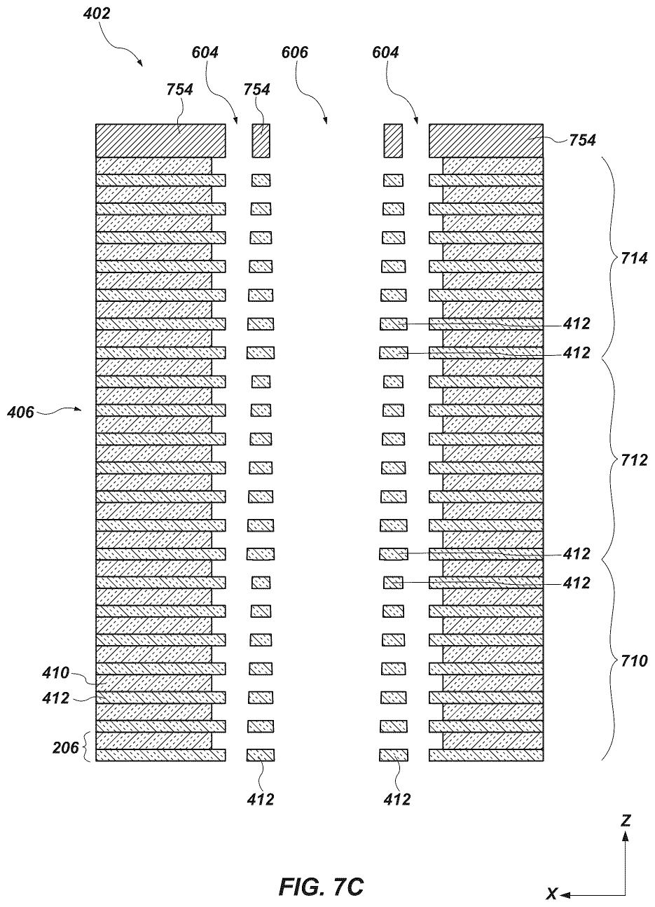

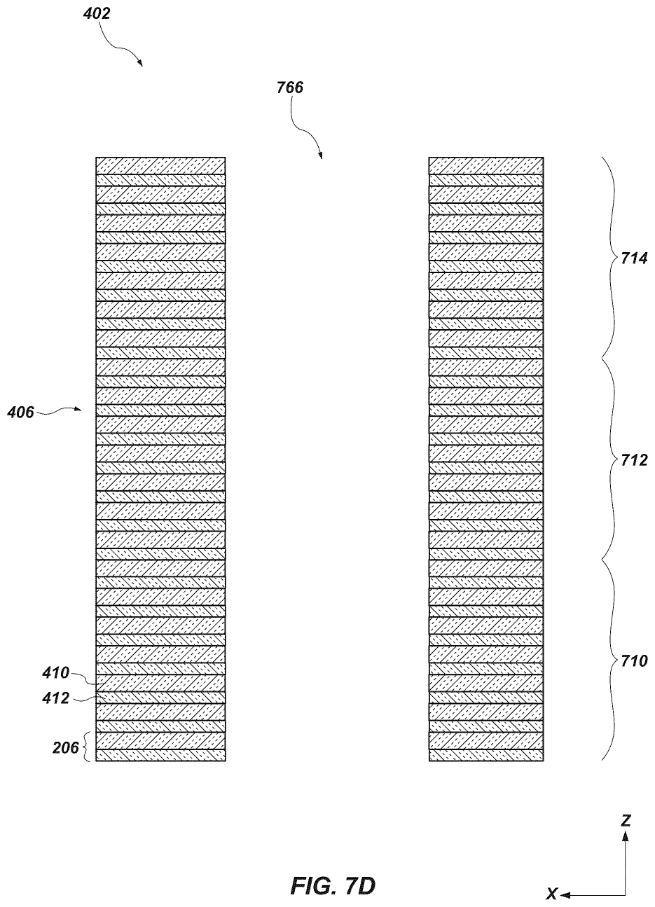

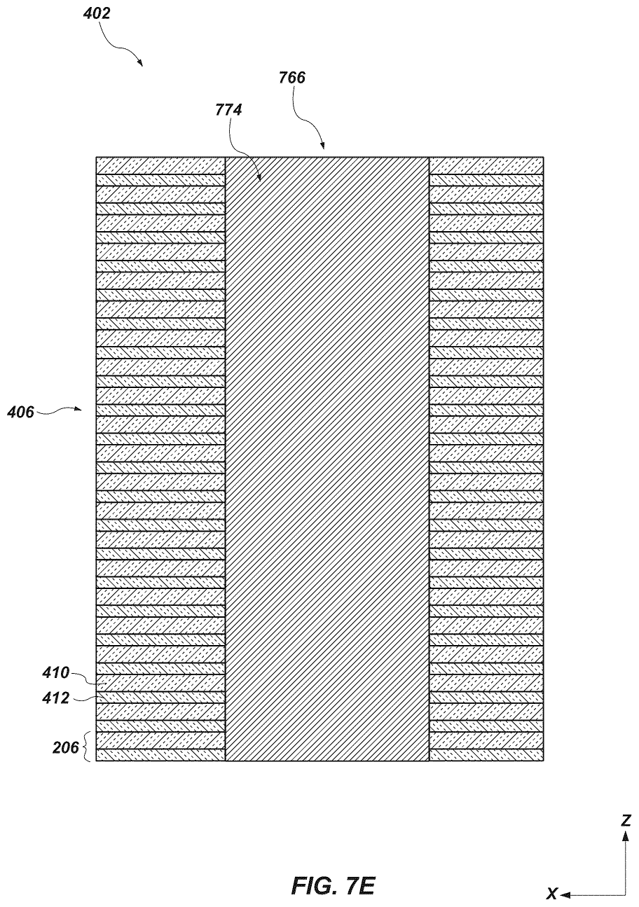

The groups of openings 602 may be horizontally positioned relative to one another to facilitate the subsequent formation of relative larger openings (i.e., merged dog-bone openings) therefrom that are then utilized to form the thin film transistors 114 (FIG. 1). Each group of openings 602 may include two wide end openings 604 and a central elongated opening 606. The two wide end openings 604 may be defined proximate opposing ends of a central elongated opening 606 in the X-direction. The central elongated opening 606 may be elongated in the X-direction. The wide end openings 604 may each be wider than the central elongated opening 606 in the Y-direction. As is discussed in greater detail below in regard to FIG. 7A through FIG. 7E, the two wide end openings 604 and the central elongated opening 606 may be merged together to form a larger opening having a general dog-bone shape within the XY-plane. Furthermore, while only three openings are shown within the group of openings 602 of FIG. 6, the disclosure is not so limited. Rather, the group of openings 602 may include any number of openings that may be merged to form a larger opening having a general dog-bone shape within the XY-plane.

FIG. 7A through FIG. 7E include simplified, vertical cross-sectional views of an example portion of the microelectronic device structure 402 taken about line A-A of FIG. 6, at different processing stages of merging various groups of openings 602 together. While FIG. 7A through FIG. 7E depict only three openings (i.e., two wide end openings 604 and a central elongated opening 606) for simplicity and to enable showing enlarged structures and details within the drawings, any number of openings may be merged together through the processes described. FIG. 7A may represent a structure of the microelectronic device structure 302 after the processing steps described above in regard to FIG. 5 and/or FIG. 6.

Referring specifically to FIG. 6 and FIG. 7A together, multiple preliminary deck structures are shown stacked above one another (e.g., a first preliminary deck structure 710, a second preliminary deck structure 712 stacked over the first preliminary deck structure 710, and a third preliminary deck structure 714 stacked above the second preliminary deck structure 712). Each of the preliminary deck structures 710, 712, 714 constitutes a portion of the overall stack structure 406; and includes some of the tiers 206 of insulative material 410 and other insulative material 412, and two wide end openings 604 and a central elongated opening 606 vertically extending through some of the tiers 206 thereof in the Z-direction. The two wide end openings 604 and a central elongated opening 606 are filled with the sacrificial material 744, forming the pillars 752. As used herein, “openings” will be understood to include both unfilled openings (e.g., void spaces) and filled openings.

As noted above, each group of openings 602 within the thin film transistor regions 136 may be merged together using one or more etching processes. For instance, a first mask material 754 may be formed over the top surface of the stack structure 406 (i.e., on a top surface of the third preliminary deck structure 714), and the first mask material 754 may be patterned to form patterned openings at least partially horizontally overlapping the two wide end openings 604 and the central elongated opening 606 of the groups of openings 602 within the thin film transistor regions 136. The first mask material 754 may be patterned to include the patterned dog-bone openings 506 utilizing any suitable methodology. For instance, in some embodiments, a photoresist material is formed on or over the first mask material 754, is patterned (e.g., photo exposed and developed), and then openings formed in the patterned photoresist material are extended into the first mask material 754 to form the patterned openings. The first mask material 754 may be removed during subsequent processing stages, or may remain in a final device formed through the methods of the disclosure. The first mask material 754 may be formed of and include dielectric material, such as dielectric nitride material (e.g., silicide nitride).

Referring to FIG. 6 and FIG. 7B together, the first mask material 754 and the patterned openings may be employed to remove the sacrificial material 744 within the two wide end openings 604 and the central elongated opening 606 through one or more etch processes. For instance, the sacrificial material 744 may be removed from the two wide end openings 604 and the central elongated opening 606 horizontally overlapping the patterned openings using an etching process (e.g., an anisotropic etching process) that selectively removes exposed portions of the sacrificial material 744 without removing portions of the insulative material 410 and the other insulative material 412 of the tiers 206. Furthermore, the sacrificial material 744 within the two wide end openings 604 and the central elongated opening 606 of each of the first preliminary deck structure 710, the second preliminary deck structure 712, and the third preliminary deck structure 714 may be removed through a single etching process. Accordingly, respective wide end openings 604 and central elongated openings 606 within the first preliminary deck structure 710, the second preliminary deck structure 712, and the third preliminary deck structure 714 that horizontally overlap one another (e.g., in the X-direction) may be merged together in a vertical direction (e.g., in the Z-direction).

Referring to FIG. 6 and FIG. 7C together, the insulative material 410 (FIG. 7B) horizontally interposed between the two wide end openings 604 and the central elongated opening 606 (e.g., interposed between the two wide end openings 604 and the central elongated opening 606 in the Y-direction) may be removed. For example, the insulative material 410 may be removed using an etching process (e.g., isotropic etching process) that selectively removes exposed portions of the insulative material 410 (e.g., oxide material) without substantially removing portions of the other insulative material 412 (e.g., nitride material). In some embodiments, the insulative material 410 is removed using an oxide recess etching process. In some embodiments, the insulative material 410 of the tiers 206 of each of the first preliminary deck structure 710, the second preliminary deck structure 712, and the third preliminary deck structure 714 are removed substantially simultaneously.

Referring to FIG. 6 and FIG. 7D together, the other insulative material 412 (FIG. 7C) horizontally interposed between the two wide end openings 604 and the central elongated opening 606 may also be removed. By way of non-limiting example, the other insulative material 412 may be removed by exposing the other insulative material 412 to an etchant (e.g., a wet etchant) including one or more of phosphoric acid, sulfuric acid, hydrochloric acid, nitric acid, or another material. In some embodiments, the other insulative material 412 is removed by exposing the other insulative material 412 to a so-called “wet nitride strip” comprising phosphoric acid. In some embodiments, the other insulative material 412 of each of the first preliminary deck structure 710, the second preliminary deck structure 712, and the third preliminary deck structure 714 are removed substantially simultaneously. In some embodiments, remaining portions of the first mask material 754 are then removed by way of a CMP process.

As is shown in FIG. 7D, by removing the insulative material 410 (FIG. 7B) and the other insulative material 412 (FIG. 7C) horizontally interposed between the two wide end openings 604 and the central elongated opening 606 (FIG. 6) of a given group of openings 602 (FIG. 6), a larger merged opening 766 may be defined extending vertically through the first preliminary deck structure 710, the second preliminary deck structure 712, and the third preliminary deck structure 714. As is mentioned briefly above, these larger merged openings 766 may individually be utilized to form a thin film transistor 114 (FIG. 1).

Referring to FIG. 6 and FIG. 7E together, the larger, merged openings 766 may be filled with sacrificial material 774. For instance, the sacrificial material 774 may be formed (e.g., deposited) by way of the manners described herein. The sacrificial material 774 may include carbon or any other sacrificial material described herein.

By way of the processes described in regard to FIG. 6 through FIG. 7E, merged openings 766 having general shapes of later-formed thin film transistors 114 (FIG. 1) may be formed. For example, the merged openings 766 may have a general dog-bone shape within the XY-plane that is at least substantially the same as the shape of the dog-bone openings 506 (FIG. 5).

FIG. 8A through FIG. 8L include simplified, top-down views (FIGS. 8A, 8C, 8E, 8G, 8I, 8K) and simplified, vertical cross-sectional views (FIGS. 8B, 8D, 8F, 8H, 8J, 8L) showing different processing stages of forming the source and/or drain structures of a thin film transistor 114 (FIG. 1). The simplified, vertical cross-sectional views shown in FIGS. 8B, 8D, 8F, 8H, 8J, and 8L are about line B-B shown in FIGS. 8A, 8C, 8E, 8G, 8I, 8K, respectively. FIGS. 8A and 8B collectively depict a first processing stage in the process of forming the source and/or drain structures; FIGS. 8C and 8D collectively depict a second processing stage following the first processing stage; FIGS. 8E and 8F collectively depict a third processing stage following the second processing stage; FIGS. 8G and 8H collectively depict a fourth processing stage following the third processing stage; FIGS. 8I and 8J collectively depict a fifth processing stage following the fourth processing stage; and FIGS. 8K and 8L collectively depict a sixth processing stage following the fifth processing stage. FIG. 8A through FIG. 8L show the formation of source and/or drain structures within a single dog-bone opening 506 or merged opening 766 (FIG. 7E); however, it is understood that the processes described in regard to FIG. 8A through FIG. 8L may be utilized to form source and/or drain structures of multiple dog-bone openings 506 or merged openings 766 simultaneously and/or consecutively. For purposes of FIG. 8A through FIG. 8L, the processing stages are described in relation to a dog-bone opening 506; however, it is understood that the processes described in regard to FIG. 8A through FIG. 8L are equally applicable to the merged openings 766 described above in regard to FIG. 7A through FIG. 7E.

Referring collectively to FIG. 5, FIG. 8A, and FIG. 8B, the dog-bone opening 506 may be formed through the processes described above in regard FIG. 5 by way of one or more etching processes.

As is shown in FIG. 8A, the dog-bone opening 506 utilized to form thin film transistors 114 (FIG. 1) may have the general dog-bone shape within the XY-plane described above in regard to FIG. 5. As a result, within the XY-plane, an individual dog-bone opening 506 may include two wide end portions 508 defined on opposing ends of a central elongated portion 510 in the X-direction. The central elongated portion 510 may be elongated in the X-direction. The wide end portions 508 may each be wider than the central elongated portion 510 in the Y-direction. As is discussed in greater detail below, the source and/or drain structures of the thin film transistors 114 (FIG. 1) are formed within the wide end portions 508 of the dog-bone opening 506.

Referring next to FIG. 5, FIG. 8C, and FIG. 8D, the dog-bone opening 506 may be filled with the sacrificial material 744 through the processes described above in regard to FIG. 7E.

Referring to FIGS. 8E and 8F together, portions of the sacrificial material 744 within the wide end portions 508 of the dog-bone openings 506 may be removed to form source and/or drain trenches 820. An additional portion of the sacrificial material 744 within the central elongated portion 510 of respective ones of the dog-bone openings 506 may be maintained (e.g., may not be substantially removed).

The portions of the sacrificial material 744 may be removed through any of the removal processes described herein. For example, a mask material may be formed over the top surfaces of the stack structures 406 of the sub-tile 106 (FIG. 1) (e.g., on a top surface of the third preliminary deck structure 714 (FIG. 7A)), and the mask material may be patterned to form openings horizontally aligned with the wide end portions 508 of the dog-bone openings 506 within the thin film transistor regions 136 (FIG. 1). The mask material may be patterned to include the patterned openings utilizing any suitable methodology. For instance, in some embodiments, a photoresist material is formed on or over the mask material, is patterned (e.g., photo exposed and developed), and then openings formed in the patterned photoresist material are extended into the mask material to form the patterned openings. The mask material may be removed during subsequent processing stages or may remain in a final device formed through the methods of the disclosure. The mask material may be formed of and include a dielectric material, such as a dielectric nitride material (e.g., silicide nitride).

The mask material and the patterned openings may be employed to remove the portions of the sacrificial material 744 within the wide end portions 508 of the dog-bone openings 506 through one or more etch processes. For instance, the portions of the sacrificial material 744 may be removed using an etching process (e.g., an anisotropic etching process) that selectively removes the exposed portions of the sacrificial material 744 without removing portions of the insulative material 410 and the other insulative material 412. Additionally, the portions of the sacrificial material 744 may be removed using a directional etching process that does not significantly etch in horizontal directions (e.g., in the Y- and/or X-directions). Furthermore, the portions of the sacrificial material 744 within the wide end portions 508 of the dog-bone openings 506 extending through the first preliminary deck structure 710 (FIG. 7E), the second preliminary deck structure 712 (FIG. 7E), and the third preliminary deck structure 714 (FIG. 7E) may be removed through a single etching process or multiple etching processes.

Referring to FIG. 5, FIG. 8G, and FIG. 8H together, portions of the other insulative material 412 of respective tiers 206 of the stack structures 406 defining horizontal boundaries of the wide end portions 508 of the dog-bone opening 506 may be removed (e.g., recessed) to form horizontal recesses 824 at vertical positions of the other insulative material 412 of the tiers 206. For example, portions of the other insulative material 412 of the tiers 206 may be removed using a selective etching process (e.g., isotropic etching process) that selectively removes exposed portions of the other insulative material 412 (e.g., dielectric nitride material) without substantially removing portions of the insulative material 410 (e.g., dielectric oxide material) of the tiers 206. In some embodiments, the portions of the other insulative material 412 are removed using a wet nitride removal process. In some embodiments, the portions of the other insulative material 412 of each of the first preliminary deck structure 710 (FIG. 7E), the second preliminary deck structure 712 (FIG. 7E), and the third preliminary deck structure 714 (FIG. 7E) are removed at least substantially simultaneously. The horizontal recesses 824 may be integral and continuous with the source and/or drain trenches 820.

Referring to FIG. 5, FIG. 8I, and FIG. 8J together, semiconductor material 808 may be formed within the horizontal recesses 842 (FIGS. 8G and 8H). As shown in FIG. 8J, the semiconductor material 808 may substantially fill respective ones of the horizontal recesses 842 (FIG. 8H). Portions of the semiconductor material 808 within horizontal areas of the source and/or drain trenches 806 may be removed, such that the semiconductor material 826 is substantially confined within horizontal areas of the horizontal recesses 824 (FIGS. 8G and 8H).

The semiconductor material 826 may be formed (e.g., deposited) through any of the deposition processes described herein. For instance, the semiconductor material 826 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In some embodiments, forming the semiconductor material 826 includes overfilling the vertical spaces between insulative material 410 of the tiers 206 of the stack structures 406 with the semiconductor material 826 and then removing any excess portions through one or more etching processes. For instance, the wide end portions 508 of the dog-bone openings 506, including the vertical spaces between insulative material 410 of the tiers 206 of the stack structures 406, may be filled with the semiconductor material 826, and excess portions of the semiconductor material 826 may be subsequently removed through one or more etches.

Referring still to FIG. 5, FIG. 8I, and FIG. 8J, by ultimately filling only the horizontal recesses 824 (FIG. 8G and FIG. 8H) with the semiconductor material 826, generally annular-shaped (e.g., block-O shaped) structures of the semiconductor material 826 may be formed within the tiers 206 of the stack structure 406.

Forming the semiconductor material 826 as described above may form first semiconductor structures 828 within a first wide end portion 508 of a given dog-bone opening 506 and second semiconductor structures 832 within a second wide end portion 508 of the given dog-bone opening 506. Furthermore, in some embodiments, each of the first semiconductor structures 828 and each of the second semiconductor structures 832 includes doped semiconductor material. For example, each of the first semiconductor structures 828 and each of the second semiconductor structures 832 may be n-type doped, such as doped to an n-type dopant concentration within a range of from about 10¹⁵ cm⁻³ to about 10²⁰ cm⁻³. In additional embodiments, one of the first semiconductor structures 828 and the second semiconductor structures 832 is an n-type doped while the other of the first semiconductor structures 828 and the second semiconductor structures 832 is p-type doped, such as doped to a p-type dopant concentration within a range of from about −10¹³ cm⁻³ to about −10¹⁸ cm⁻³. In additional embodiments, one or more of the first semiconductor structures 828 and the second semiconductor structures 832 is doped (either p-doped or n-doped) to the point of saturation (e.g., greater than or equal to about −10¹⁸ cm⁻³). The doping may be accomplished utilizing any suitable processing, such as by implanting dopant (e.g., at least one n-type dopant or at least one p-type dopant) into the semiconductor material 826. A p-type dopant may include one or more of boron, aluminum, and gallium; and an n-type dopant may include one or more of arsenic, phosphorous, antimony, and bismuth.

As is discussed in further detail below, in some embodiments, the first semiconductor structures 828 respectively form one of a source structure or a drain structure of a later-formed thin film transistor 114 (FIG. 1); and the second semiconductor structures 832 respectively form another of a source structure or a drain structure of the later-formed thin film transistor 114 (FIG. 1).

Referring to FIG. 5, FIG. 8K, and FIG. 8L together, remainders (e.g., unfilled portions) of the source and/or drain trenches 820 may be filled with insulative material 836. For example, the remainders of the source and/or drain trenches 820 may be substantially filled with the insulative material 836 through any of the deposition processes described herein. The insulative material 836 may serve to isolate the annular-shaped structures of the semiconductor material 826 (e.g., the first semiconductor structures 828, the second semiconductor structures 832) of the tiers 206 of the stack structure 406 associated with (e.g., horizontally neighboring) a given wide end portion 508 from each other.

The insulative material 836 may be formed of and include insulative material such as, for example, dielectric oxide material (e.g., phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide), dielectric nitride material (e.g., silicon nitride (Si₃N₄)), dielectric oxynitride material (e.g., silicon oxynitride), dielectric carbon nitride material (e.g., silicon carbon nitride (SiCN)), dielectric carboxynitride material (e.g., silicon carboxynitride (SiOCN)), or combinations thereof. In some embodiments, the insulative material 836 is formed of and includes silicon dioxide.

In view of the foregoing, the processes described above in regard to FIG. 8A through FIG. 8E may be utilized to form source and/or drain structures 838 of the thin film transistors 114 (FIG. 1).

FIG. 9A through FIG. 9J include simplified, top-down views (FIGS. 9A, 9C, 9E, 9G, 9I) and simplified, vertical cross-sectional views (FIGS. 9B, 9D, 9F, 9H, 9J) showing different processing stages of forming additional portions of thin film transistors 114 (FIGS. 1, 8K, and 8L). The simplified, vertical cross-sectional views shown in FIGS. 9B, 9D, 9F, 9H, and 9J are about line C-C shown in FIGS. 9A, 9C, 9E, 9G, and 9I, respectively. FIGS. 9A and 9B collectively depict a first processing stage in the process of forming the additional portions of the thin film transistors 114 (FIG. 1); FIGS. 9C and 9D collectively depict a second processing stage following the first processing stage; FIGS. 9E and 9F collectively depict a third processing stage following the second processing stage; FIGS. 9G and 9H collectively depict a fourth processing stage following the third processing stage; and FIGS. 91 and 9J collectively depict a fifth processing stage following the fourth processing stage. FIG. 9A through FIG. 9J show the formation of additional portions of thin film transistors 114 (FIG. 1) within horizontal area of a dog-bone opening 506; however, it is understood that the processes described in regard to FIG. 9A through FIG. 9J may be utilized to form additional portions of the thin film transistors 114 (FIG. 1) within horizontal areas of multiple dog-bone openings 506 simultaneously and/or consecutively.

Referring collectively FIG. 9A and FIG. 9B, remaining portions of the sacrificial material 744 (FIGS. 8K and 8L) within the central elongated portion 510 of the dog-bone opening 506 may be removed to form a channel trench 904. The remaining portions of the sacrificial material 744 (FIG. 8K) may be removed through any of the removal processes described herein. For example, a mask material may be formed over the top surfaces of the stack structures 406 of the sub-tile 106 (e.g., on a top surface of the third preliminary deck structure 714 (FIG. 4)), and the mask material may be patterned to form an opening horizontally aligned with the central elongated portion 510 of the dog-bone openings 506 within the thin film transistor regions 136 (FIG. 1). The mask material may be patterned to include the patterned openings utilizing any suitable methodology. For instance, in some embodiments, a photoresist material is formed on or over the mask material, is patterned (e.g., photo exposed and developed), and then openings formed in the patterned photoresist material are extended into the mask material to form the patterned openings. The mask material may be removed during subsequent processing stages or may remain in a final device formed through the methods of the disclosure. The mask material may be formed of and include a dielectric material, such as a dielectric nitride material (e.g., silicide nitride).

The mask material and the patterned openings may be employed to remove the remaining portions of the sacrificial material 744 (FIG. 8K) within the central elongated portions 510 of the dog-bone openings 506 to form the channel trenches 904 through one or more etch processes. For instance, the remaining portions of the sacrificial material 744 (FIG. 8K) may be removed using an etching process (e.g., an anisotropic etching process) that selectively removes exposed portions of the sacrificial material 744 (FIG. 8K) without removing portions of the insulative material 410 and the other insulative material 412. Additionally, the remaining portions of the sacrificial material 744 (FIG. 8K) may be removed using a directional etching process that does not significantly etch in horizontal directions (e.g., in the Y- and/or X-directions). Furthermore, the remaining portions of the sacrificial material 744 (FIG. 8K) within the central elongated portion 510 of the dog-bone openings 506 extending through the first preliminary deck structure 710 (FIG. 7E), the second preliminary deck structure 712 (FIG. 7E), and the third preliminary deck structure 714 (FIG. 7E) may be removed through a single etching process or multiple etching processes.

Referring to FIG. 5, FIG. 9C, and FIG. 9D together, additional portions of the other insulative material 412 of respective tiers 206 of the stack structure 406 defining horizontal boundaries of the channel trench 904 may be removed (e.g., recessed) to form additional horizontal recesses 918 at vertical positions of the other insulative material 412 of the tiers 206. For example, portions of the other insulative material 412 of the tiers 206 may be removed using a selective etching process (e.g., isotropic etching process) that selectively removes exposed portions of the other insulative material 412 (e.g., dielectric nitride material) without substantially removing portions of the insulative material 410 (e.g., dielectric oxide material) of the tiers 206. In some embodiments, the additional portions of the other insulative material 412 are removed using a wet nitride removal process. In some embodiments, the additional portions of the other insulative material 412 of each of first preliminary deck structure 710 (FIG. 7E), the second preliminary deck structure 712 (FIG. 7E), and the third preliminary deck structure 714 (FIG. 7E) is removed at least substantially simultaneously. The additional horizontal recesses 918 may be integral and continuous with the channel trench 904.

Referring to FIG. 5, FIG. 9E, and FIG. 9F together, channel material 1004 may be formed within the additional horizontal recesses 918 (FIGS. 9C and 9D). As shown in FIG. 9F, the channel material 920 may substantially fill respective ones of the additional horizontal recesses 918 (FIG. 9C). Portions of the channel material 920 within a horizontal area of the channel trench 904 may be removed, such that the channel material 920 is substantially confined within horizontal areas of the additional horizontal recesses 918 (FIG. 9C).

The channel material 920 may be formed (e.g., deposited) through any of the deposition processes described herein. For instance, the channel material 920 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In some embodiments, forming the channel material 920 includes overfilling the vertical spaces between insulative material 410 of the tiers 206 of the stack structure 406 with the channel material 920 and then removing any excess portions through one or more etching processes. For instance, the central elongated portion 510 of the dog-bone openings 506, including the vertical spaces between insulative material 410 of the tiers 206 of the stack structure 406, may be filled with the channel material 920, and excess portions of the channel material 920 may be subsequently removed.

The channel material 920 may be formed of and include one or more of a semiconductor material (at least one elemental semiconductor material, such as polycrystalline silicon; at least one III-V compound semiconductor material, at least one II-VI compound semiconductor material, at least one organic semiconductor material, GaAs, InP, GaP, GaN, other semiconductor materials) and an oxide semiconductor material. In some embodiments, the channel material 920 includes amorphous silicon or polysilicon. In some embodiments, the channel material 920 is formed of and includes doped semiconductor material.

Referring to FIG. 5, FIG. 9G, and FIG. 9H together, a gate insulative liner 924 may be formed within the channel trench 904 of the dog-bone openings 506. For example, a gate insulative liner 924 may be formed to horizontally neighbor exposed surfaces of the insulative material 410 of the tiers 206 of the stack structure 406 and the exposed surfaces of the channel material 920 at the vertical positions of the other insulative material 412 of the tiers 206 of the stack structure 406. Put another way, the gate insulative liner 924 may be formed to line vertically oriented surfaces of the insulative material 410 and the channel material 920 partially defining boundaries of the channel trench 904 (or a remainder of the channel trench 904).

The gate insulative liner 924 may be formed (e.g., deposited) through any of the deposition processes described herein. For instance, the gate insulative liner 924 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In additional embodiments, the gate insulative liner 924 is formed (e.g., conformally deposited) inside and outside of the channel trenches 904 and then portions of the gate insulative liner 924 outside of the channel trenches 904 are removed (e.g., by way of CMP) while portions of the gate insulative liner 924 within the channel trenches 904 are maintained. As is shown in FIG. 9H, bottom portions of the gate insulative liner 924 lining the bottom of the channel trench 904 may be removed through one or more subsequent etching processes. Additionally, within the XY-plane, the gate insulative liner 924 may have a generally annular shape (e.g., a generally block-O shape).

The gate insulative liner 924 may be formed of and include insulative material such as, for example, one or more of dielectric oxide material (e.g., phosphosilicate glass (PSG), borosilicate glass (BSG), fluorosilicate glass (FSG), borophosphosilicate glass (BPSG), silicon dioxide, titanium dioxide, zirconium dioxide, hafnium dioxide, tantalum oxide, magnesium oxide, aluminum oxide, niobium oxide, molybdenum oxide, strontium oxide, barium oxide, yttrium oxide), dielectric nitride material (e.g., silicon nitride (Si₃N₄)), dielectric oxynitride material (e.g., silicon oxynitride), dielectric carbon nitride material (e.g., silicon carbon nitride (SiCN)), and dielectric carboxynitride material (e.g., silicon carboxynitride (SiOCN)). In some embodiments, the gate insulative liner 924 is formed of and includes silicon dioxide.

As is shown in FIG. 9G and FIG. 9H, the gate insulative liner 924 may define a gate space 928 within the channel trench 904. For instance, a remaining space within the channel trench 904 not occupied by the gate insulative liner 924 may form the gate space 928. The horizontal boundaries of the gate space 928 may be defined by an inner side surface 930 (e.g., an inner sidewall) of the gate insulative liner 924.

Referring to FIG. 9I and FIG. 9J together, a gate material 932 may be formed within the gate space 928 (FIG. 9G and FIG. 9H). For example, the gate material 932 may be formed to substantially fill the gate space 928 and to horizontally neighbor the inner side surface 930 (FIG. 9G and FIG. 9H) of the gate insulative liner 924.

The gate material 932 may be formed (e.g., deposited) through any of the deposition processes described herein. For instance, the gate material 932 may be formed through one or more of spin coating, blanket coating, chemical vapor deposition (CVD), atomic layer deposition (ALD), plasma enhanced ALD, physical vapor deposition (PVD), plasma enhanced chemical vapor deposition (PECVD), or low-pressure chemical vapor deposition (LPCVD). In additional embodiments, the gate material 932 is formed inside and outside of the gate spaces 928 and then portions of the gate material 932 outside of the gate spaces 928 are removed (e.g., by way of CMP) while the portion of the gate material 932 within the gate spaces 928 is maintained.

The gate material 932 may be formed of and include conductive material. By way of non-limiting example, the gate material 932 may be formed of and include one or more of W, Ru, Mo, TiN_{y}, or any other metallic film. The gate material 932 may form gates 934 of the thin film transistors 114.

Referring still to FIG. 9I and FIG. 9J, the thin film transistors 114 may respectively have a horizontal length in the X-direction within a range of from about 250 nm to about 350 nm. For example, the thin film transistors 114 may respectively have a horizontal length in the X-direction of about 300 nm. Additionally, the thin film transistors 114 may respectively have a horizontal width in the Y-direction within a range of from about 100 nm to about 140 nm. For instance, the thin film transistors 114 may respectively have a horizontal width in the Y-direction of about 120 nm. Furthermore, the gate material 932 (e.g., the gate structure) of the thin film transistors 114 may have a horizontal length in the X-direction within a range of from about 150 nm to about 180 nm. For example, the gate material 932 (e.g., the gate) of the thin film transistor 114 may have a horizontal length in the X-direction of about 165 nm. Moreover, the gate material 932 may have a horizontal width in the Y-direction within a range of from about 10 nm to about 50 nm. For instance, the gate material 932 may have a horizontal width in the Y-direction of about 30 nm. Also, the gate insulative liner 924 may have a horizontal width in the Y-direction within a range of from about 5 nm to about 20 nm. For example, the gate insulative liner 924 may have a horizontal width in the Y-direction of about 10 nm. Also, the channel material 920 may have a horizontal width in the Y-direction within a range of from about 5 nm to about 20 nm. For instance, the channel material 920 may have a horizontal width in the Y-direction of about 10 nm.

FIG. 10A through FIG. 15B show various simplified views of a portion of an array region 132 of a sub-tile 106 (FIG. 1) at different processing stages of a method of forming the microelectronic device 102 (FIG. 1), according to one or more embodiments of the disclosure. In some embodiments, FIG. 10A through FIG. 15B show processing stages that are subsequent to the formation of the thin film transistors 114 (FIG. 9I) described above in regard to FIG. 8A through FIG. 9J. In alternative embodiments, FIG. 10A through FIG. 15B show processing stages that are subsequent to the formation of source and/or drain structures 838 (FIG. 8K) of the thin film transistors 114 (FIG. 9I) described above in regard to FIG. 8A through FIG. 8L but prior to processing stages described above in regard to FIG. 9A through FIG. 9J.

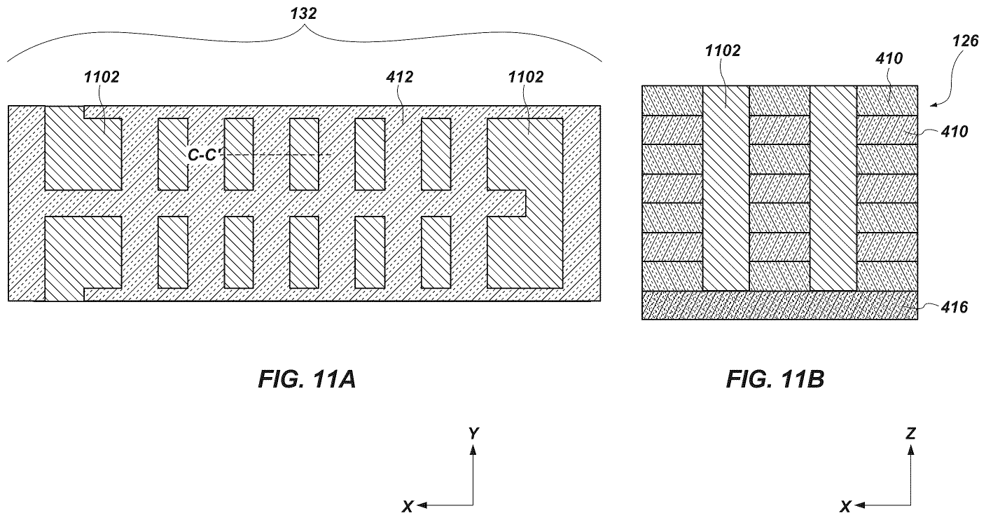

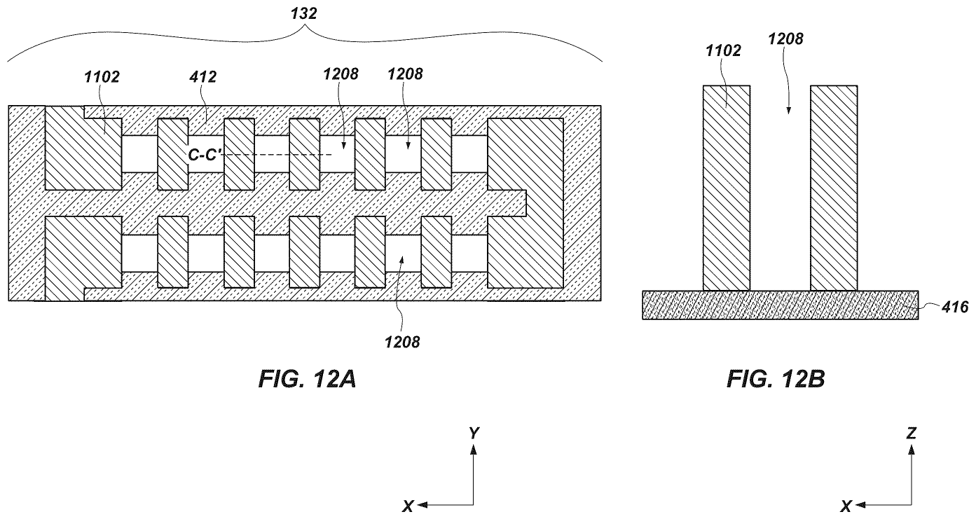

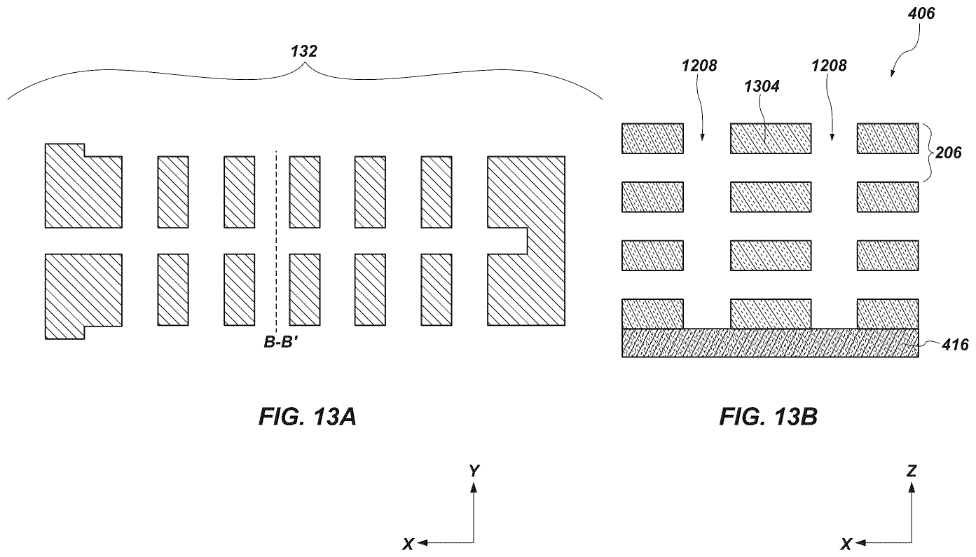

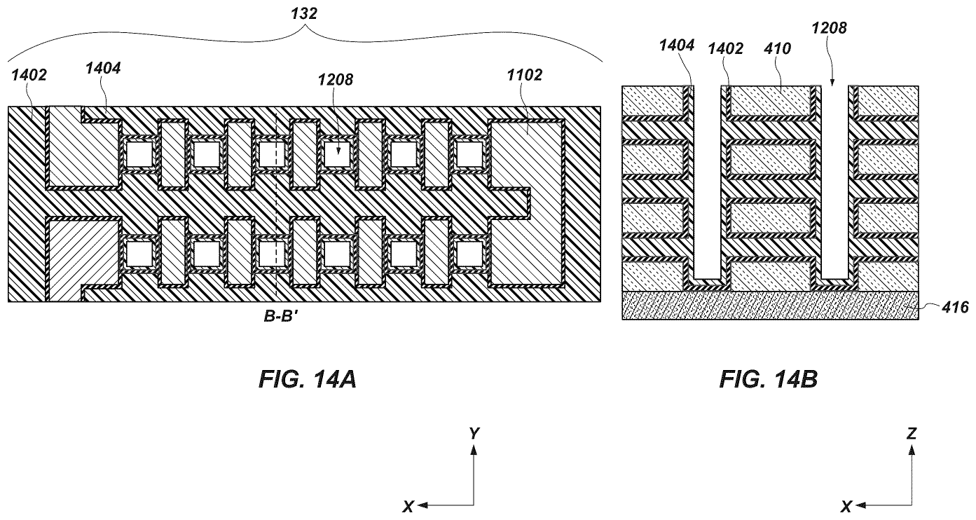

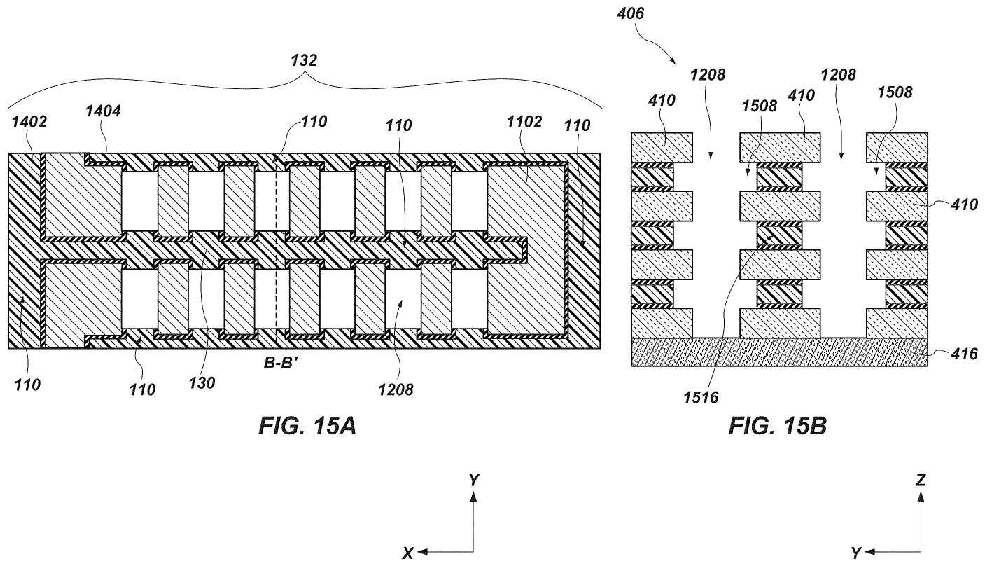

FIG. 10A, FIG. 11A, FIG. 12A, FIG. 13A, FIG. 14A, and FIG. 15A are simplified partial horizontal cross-sectional views of a portion of an array region 132 of a sub-tile 106 (FIG. 1), in accordance with embodiments of the disclosure. Furthermore, FIG. 10A, FIG. 11A, FIG. 12A, FIG. 13A, FIG. 14A, and FIG. 15A show a horizontal cross-sectional view of the portion of the array region at an elevation that is coplanar with an other insulative material 412 of the tiers 206 (FIG. 4) of the stack structure 406 (FIG. 4) of the sub-tile 106 (FIG. 1). FIG. 10B, FIG. 11B, and FIG. 12B are vertical cross-sectional views of the portion of the array region 132 of the sub-tile 106 (FIG. 1) taken about line C-C of FIGS. 10A through 12A, respectively. FIG. 13B, FIG. 14B, and FIG. 15B are vertical cross-sectional views of the portion of the array region 132 of the sub-tile 106 (FIG. 1) taken about line B-B of FIGS. 13A through 15A, respectively.

Referring to FIG. 4, FIG. 10A, and FIG. 10B together, various isolation openings 1006 are formed through the tiers 206 of the stack structure 406. The isolation openings 1006 may be formed utilizing a mask structure (e.g., a patterned photoresist material, a patterned hard mask material) with a pattern of isolation openings 1006 defined therein. For example, the pattern may be defined in a photoresist material (e.g., through selective light exposure using a reticle followed by development) to form a patterned photoresist material, and then the patterned photoresist material may be used to etch the pattern through the stack structure 406 to define the isolation openings 1006 in the array regions 132 of the sub-tiles 106 (FIG. 1). For instance, the isolation openings 1006 may be formed via one or more directional etches (i.e., anisotropic etches). Additionally, when the stack structure 406 of the microelectronic device structure 402 includes multiple preliminary deck structures stacked on top of each other in the Z-direction, the isolation openings 1006 may be formed in each preliminary deck structure, respectively. For example, upon formation of a first preliminary deck structure (e.g., lowermost preliminary deck structure), the isolation openings 1006 are formed in the first preliminary deck structure and filled (described below). Subsequently, a second preliminary deck structure is formed above the first preliminary deck structure, and more of the isolation openings 1006 are formed in the second preliminary deck structure and filled. Any further preliminary deck structures formed above of the second preliminary deck structure may have further of the isolation openings 1006 formed therein and filled in the same manner. In other words, the isolation openings 1006 may be formed and then filled on a deck-by-deck basis.

Referring to FIG. 5, FIG. 6, FIG. 10A, and FIG. 10B together, in some embodiments, the isolation openings 1006 and the dog-bone openings 506 and/or the groups of openings 602 are formed during the same etching processes. In additional embodiments, the isolation openings 1006 and the dog-bone openings 506 and/or the groups of openings 602 are formed during different etching processes.

Referring again to FIG. 4, FIG. 10A, and FIG. 10B together, the isolation openings 1006 may include a grid of relatively smaller openings 1008 including columns of smaller openings 1008 extending in the Y-direction and rows of smaller openings 1008 extending the X-direction. The isolation openings 1006 may further include relatively larger openings 1010 formed through the tiers 206 of the stack structure 406 outside of a horizontal area of the grid of smaller openings 1008. For instance, each larger opening 1010 may be formed adjacent to an outermost column of smaller openings 1008 in the X-direction, and a length of the larger opening 1010 may span two neighboring rows of the smaller openings 1008 in the Y-direction. Furthermore, positions of the larger openings 1010 on a first side of the grid of smaller openings 1008 may be offset in the Y-direction from positions of larger openings 1010 on a second, opposite side of the grid of smaller openings. For example, for four neighboring rows of smaller openings 1008 within the grid of smaller openings 1008, which, for purposes of this example, are referred to as row 1, row 2, row 3, and row 4, in consecutive order, a first larger opening 1010 on a first side of the grid may span rows 1 and 2, a second larger opening 1010 on a second opposite side of the grid may span rows 2 and 3, and a third larger opening 1010 on the first side of the grid and horizontally neighboring the first larger opening 1010 may span rows 3 and 4. As a result, the isolation openings 1006 may defined a general serpentine pattern of openings.

Referring to FIG. 4, FIG. 11A, and FIG. 11B together, the isolation openings 1006 may be filled within an isolation material to form isolation structures 1102. The isolation structures 1102 may be formed (e.g., deposited) by way of the manners described herein. The isolation material, and as a result, the isolation structures 1102, may include one or more of dielectric oxide material (e.g., silicon dioxide (SiO₂)), phosphosilicate glass, borosilicate glass, borophosphosilicate glass, fluorosilicate glass, titanium dioxide (TiO₂), hafnium oxide (HfO₂), zirconium dioxide (ZrO₂), hafnium dioxide (HfO₂), tantalum oxide (TaO₂), magnesium oxide (MgO), and aluminum oxide (Al₂O₃). In some embodiments, the isolation material, and as a result, the isolation structures 1102, are formed of and include silicon dioxide.

Referring to FIG. 4, FIG. 12A, and FIG. 12B together, pillar openings 1208 are formed through the tiers 206 of the stack structure 406. The pillar openings 1208 may be formed generally along the serpentine path defined by the isolation openings 1006 and the associated isolation structures 1102. Furthermore, the pillar openings 1208 may be formed horizontally between neighboring isolation structures 1102 along the serpentine path. In view of the foregoing, the pillar openings 1208 may be oriented relative to one another in a grid pattern with rows and columns. The pillar openings 1208 may be formed by way of any of the manners described herein.

Referring to FIG. 4, FIG. 13A, and FIG. 13B together, subsequent to forming the pillar openings 1208, portions of the other insulative material 412 (FIG. 12A) of the stack structures 406 of the sub-tile 106 (FIG. 1) relatively proximate the pillar openings 1208 may be removed by way of the pillar openings 1208 as part of a so-called “replacement gate” or “gate last” process. By way of non-limiting example, the portions of the other insulative material 412 (FIG. 12A) may be removed by exposing the other insulative material 412 (FIG. 12A) to an etchant (e.g., a wet etchant) comprising one or more of phosphoric acid, sulfuric acid, hydrochloric acid, nitric acid, or another material. In some embodiments, the portions of the other insulative material 412 (FIG. 12A) are removed by exposing the other insulative material 412 (FIG. 12A) to a so-called “wet nitride strip” comprising phosphoric acid.

As noted above, the process of removing portions of the other insulative material 412 (FIG. 12A) may be timed and tailored such that at least some portions of the other insulative material 412 at boundaries between sub-tiles 106 are maintained. In other words, an amount of time the other insulative material 412 of the tiers 206 is exposed to an etchant can be selected such that at least some portions of the other insulative material 412 at boundaries between sub-tiles 106 are maintained. As a result, a vertical stack of insulative materials 410 and other insulative material 412 of the original stack structure 406 may be maintained at boundaries between sub-tiles 106 such that a horizontal barrier of a vertical stack of insulative materials 410 and other insulative material 412 separates at least portions the sub-tiles 106 (FIG. 1) of the microelectronic device 102 (FIG. 1) from each other in the Y-direction. In particular, the maintained vertical stacks of insulative materials 410 and other insulative material 412 (i.e., insulative structures 108 (FIG. 1)) may physically separate (e.g., isolate) portions (e.g., memory array regions 132, thin film transistor regions 136, local word lines 110, etc.) of horizontally neighboring sub-tiles 106 (FIG. 1) of the microelectronic device 102 (FIG. 1) from one another in the Y-direction.

Referring to FIG. 4, FIG. 14A, and FIG. 14B together, after removal of the portions of the other insulative material 412, conductive material 1402 may be formed within the resulting void spaces through the pillar openings 1208. The conductive material 1402 of some of the tiers 206 may serve as portions of local word line structures (e.g., local word lines 110 (FIG. 1)) and may be formed to couple to source and/or drain structures 838 (FIG. 8K) of the thin film transistors 114 (FIG. 1). Forming the conductive material 1402, and the resulting local word lines 110, through the pillar openings 1208 (i.e., the grid of pillar openings 1208) enables robust connectivity between the conductive material 1402 (i.e., the resulting local word lines 110) and the source and/or drain structures 838 (FIG. 8K) of the thin film transistors (FIG. 1). Moreover, forming the conductive material 1402, and the resulting local word lines 110, through the pillar openings 1208 (i.e., the grid of pillar openings 1208) enables more complex shapes of conductive material 1402 and local word lines 110, in comparison to conventional slot-enabled so-called “replacement gate” or “gate last” processes.

The conductive material 1402 may be formed of and include one or more of at least one metal (e.g., tungsten, titanium, nickel, platinum, rhodium, ruthenium, iridium, aluminum, copper, molybdenum, silver, gold), at least one alloy, at least one metal-containing material (e.g., metal nitrides, metal silicides, metal carbides, metal oxides), a material including at least one of titanium nitride (TiN), tantalum nitride (TaN), tungsten nitride (WN), titanium aluminum nitride (TiAlN), iridium oxide (IrOₓ), ruthenium oxide (RuOₓ), a conductively-doped semiconductor material (e.g., conductively-doped silicon, conductively-doped germanium, conductively-doped silicon germanium), other materials exhibiting electrical conductivity, or combinations thereof. In some embodiments, the conductive material 1402 is tungsten.

In some embodiments, the conductive material 1402 includes a conductive liner material 1404 around the conductive material 1402, such as between the conductive material 1402 and the insulative material 410 and/or between the conductive material 1402 and the isolation structures 1102. The conductive liner material 1404 may include, for example, a seed material from which the conductive material 1402 may be formed. The conductive liner material 1404 may be formed of and include, for example, a metal (e.g., titanium, tantalum), a metal nitride (e.g., tungsten nitride, titanium nitride, tantalum nitride), or another material. In some embodiments, the conductive liner material 1404 is titanium nitride.

Referring to FIG. 4, FIG. 15A, and FIG. 15B, portions of the conductive material 1402 and the conductive liner material 1404 of respective tiers 206 of the stack structure 406 defining horizontal boundaries of the pillar openings 1208 may be removed (e.g., recessed) to form additional horizontal recesses 1508 at vertical positions of the conductive material 1402 and the conductive liner material 1404 of the tiers 206. For example, portions of the conductive material 1402 and the conductive liner material 1404 of the tiers 206 may be removed using a selective etching process (e.g., isotropic etching process) that selectively removes exposed portions of the conductive material 1402 and the conductive liner material 1404 (e.g., tungsten (W) and/or titanium nitride) without substantially removing portions of the insulative material 410 (e.g., dielectric oxide material) of the tiers 206. In some embodiments, the portions of the conductive material 1402 and the conductive liner material 1404 are removed using a wet nitride removal process. In some embodiments, the portions of the conductive material 1402 and the conductive liner material 1404 are removed are removed at least substantially simultaneously. The additional horizontal recesses 1508 may be integral and continuous with the pillar openings 1208.

Recessing the conductive material 1402 and the conductive liner material 1404 may at least partially define horizontal boundaries of the extensions 130 of the local word lines 110 and may at least partially define the serpentine path between the local word lines 110 within the array regions 132 of the sub-tiles 106 (FIG. 1).

Subsequent to the processing stages described in regard to FIGS. 10A-15B, memory cells 120 (FIG. 1) may be formed within the pillar openings 1208. For example, resistive random-access memory (RRAM) cells, dynamic random access memory (DRAM) cells (e.g., trench-capacitor cells, stacked-capacitor cells), phase change memory (PCM) cells, and/or conductive metal-oxide material cells may be formed within the pillar openings 1208.

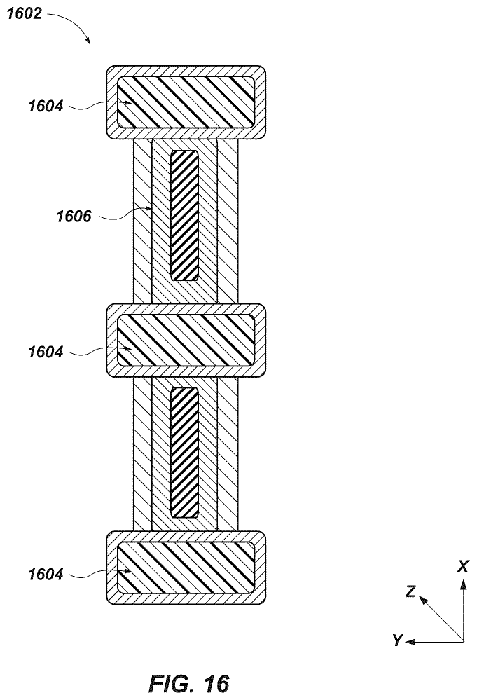

FIG. 16 shows a schematic diagram of a multi-gate thin film transistor 1602 that can be utilized in the thin film transistor region 136 (FIG. 1) of the microelectronic device 102 (FIG. 1). The multi-gate thin film transistors 1602 configuration shown in FIG. 16 may be formed using the processes previously described herein with reference to FIG. 1 through FIG. 9J. An individual multi-gate thin film transistor 1602 may include a generally linear arrangement of multiple source and/or drain structures 1604 and channel structures 1606 horizontally positioned next to each other. Furthermore, the multiple source and/or drain structures 1604 and channel structures 1606 may be horizontally position relative to one another in an alternating pattern (e.g., source and/or drain structure 1604, channel structure 1606, source and/or drain structure 1604, channel structure 1606, etc.).

The source and/or drain structures 1604 may include any of the structures described above in regard to FIG. 8A through FIG. 9J and the first semiconductor structure 828 and the second semiconductor structure 832. Furthermore, the channel structures 1606 may include any of the channel structures described above in regard FIG. 9A through FIG. 9J. The multi-gate thin film transistors 1602 may provide thin film transistors 114 (FIG. 9J) in series, and having thin film transistors 114 (FIG. 9J) in series may provide protection against shorts between source and/or drain structures 1604.

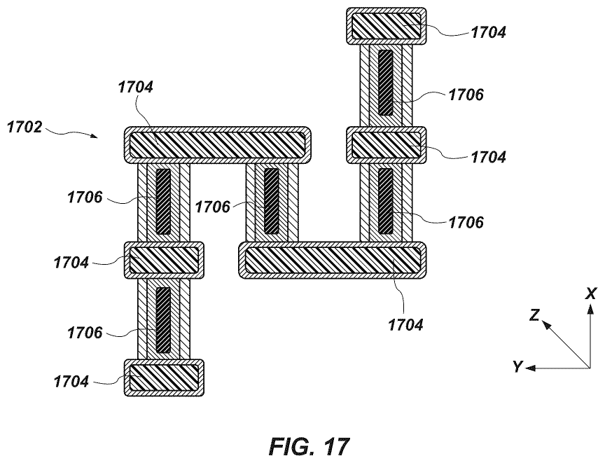

FIG. 17 shows a schematic diagram of another multi-gate thin film transistors 1702 according to one or more embodiments. The multi-gate thin film transistor 1702 configuration shown in FIG. 17 may be formed using the processes previously described herein with reference to FIG. 1 through FIG. 9J. An individual multi-gate thin film transistor 1702 may include a generally serpentine-shaped arrangement of multiple source and/or drain structures 1704 and channel structures 1706. Furthermore, the multiple source and/or drain structures 1704 and channel structures 1706 may be oriented relative to one another in an alternating pattern (e.g., source and/or drain structure 1704, channel structure 1706, source and/or drain structure 1704, channel structure 1706, etc.) along an overall, non-linear (e.g., serpentine) path of the multi-gate thin film transistor 1702.

Embodiments include a microelectronic device including a stack structure comprising tiers respectively including a local word line structure, each local word line comprising a backbone member and extensions extending from the backbone member, the extensions being coupled to memory cells of an array region of the stack structure and thin film transistors at vertical positions of the tiers of the stack structure. Each of the thin film transistors includes a first source/drain region coupled to a backbone member of a respective local word line on a horizontal side of the backbone member opposite the extensions of the respective local word line, a second source/drain region coupled to a global word line and a channel region horizontally extending from the first source/drain region to the second source/drain region. The channel region includes a relatively smaller width than each of the first source/drain region and the second source/drain region in a first horizontal direction and a relatively larger length than each of the first source/drain region and the second source/drain region in a second horizontal direction different than the first horizontal direction, and a gate horizontally neighboring the channel region.

One or more embodiments include a method of forming a microelectronic device. The method may include forming a stack structure comprising a vertically alternating sequence of insulative structures and other insulative structures arranged in tiers, forming dog-bone openings horizontally between an array region of the stack structure and a staircase structure of the microelectronic device, the dog-bone openings extending into the stack structure from an uppermost surface of the stack structure, each of the dog-bone openings comprising: a central elongated portion extending in a first horizontal direction; and two wide end portions at opposing horizontal ends of the central elongated portion, forming thin film transistors within the dog-bone openings and at each tier of the stack structure, forming local word lines within the array region of the stack structure, each local word line comprising: a backbone member extending in a second horizontal direction orthogonal to the first horizontal direction and extensions extending horizontally from the backbone member in a direction parallel or collinear to the first horizontal direction.

Some embodiments include microelectronic device including a stack structure comprising: tiers, wherein, within an array region of the stack structure, each tier respectively comprises: a first local word line comprising a first backbone member and first extensions extending orthogonally from the first backbone member in a first direction; and a second local word line comprising a second backbone member and second extensions extending orthogonally from the second backbone member in a second, opposite direction, wherein, at least multiple first extensions of the first local word line are each horizontally nested between second extensions of the second local word line, and wherein at least multiple second extensions of the second local word line are each horizontally nested between first extensions of the first local word line, and memory cells formed within the array region of the stack structure, each memory cell being coupled to and horizontally between at least one first extension of a first local word line and at least one a second extension of a second local word line; first in-tier word line decoder structures, each being coupled to a first backbone member of a respective first local word line on a horizontal side of the first backbone member opposite the first extensions, each of the first in-tier word line decoder structures comprising first thin film transistors, and second in-tier word line decoder structures, each being coupled to a second backbone member of a respective second local word line on a horizontal side of the second backbone member opposite the second extensions, each of the second in-tier word line decoder structures comprising second thin film transistors.

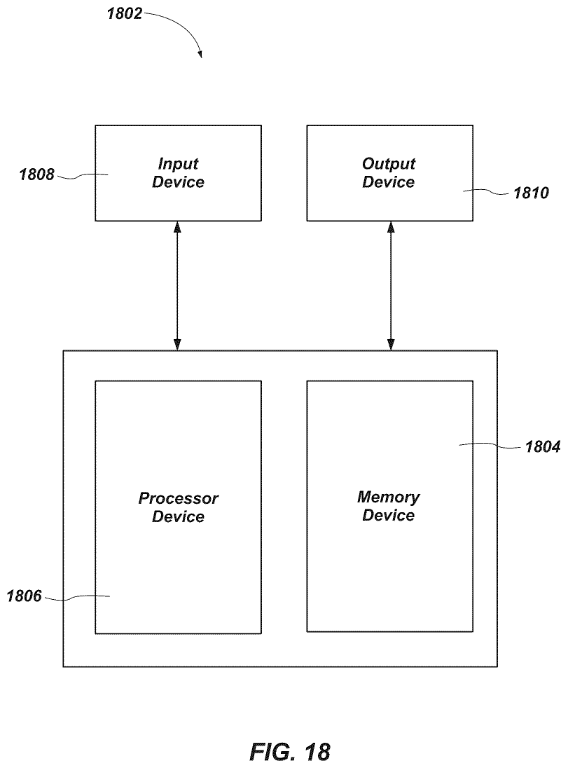

FIG. 18 is a block diagram of an electronic system 1802, in accordance with embodiments of the disclosure. The electronic system 1802 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 1802 includes at least one memory device 1804. The memory device 1804 may include, for example, an embodiment of a microelectronic device structure and/or a microelectronic device previously described with respect to one or more of FIG. 1, FIG. 16, and FIG. 17.

The electronic system 1802 may further include at least one electronic signal processor device 1806 (often referred to as a “microprocessor”). The electronic signal processor device 1806 may, optionally, include an embodiment of a microelectronic device structure and/or a microelectronic device previously described within with respect to one or more of FIG. 1, FIG. 16, and FIG. 17. The electronic system 1802 may further include one or more input devices 1808 for inputting information into the electronic system 1802 by a user, such as, for example, a mouse or other pointing device, a keyboard, a touchpad, a button, or a control panel. The electronic system 1802 may further include one or more output devices 1810 for outputting information (e.g., visual or audio output) to a user such as, for example, a monitor, a display, a printer, an audio output jack, a speaker, etc. In some embodiments, the input device 1808 and the output device 1810 include a single touchscreen device that can be used both to input information to the electronic system 1802 and to output visual information to a user. The input device 1808 and the output device 1810 may communicate electrically with one or more of the memory device 1804 and the electronic signal processor device 1806.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

What is claimed is:

1. A microelectronic device, comprising:
a stack structure comprising tiers respectively including a local word line structure, each local word line comprising a backbone member and extensions extending from the backbone member, the extensions being coupled to memory cells of an array region of the stack structure; and
thin film transistors at vertical positions of the tiers of the stack structure and respectively comprising:
a first source/drain region coupled to a backbone member of a respective local word line on a horizontal side of the backbone member opposite the extensions of the respective local word line;
a second source/drain region coupled to a global word line; and
a channel region horizontally extending from the first source/drain region to the second source/drain region, the channel region comprising:
a relatively smaller width than each of the first source/drain region and the second source/drain region in a first horizontal direction; and
a relatively larger length than each of the first source/drain region and the second source/drain region in a second horizontal direction different than the first horizontal direction; and
a gate horizontally neighboring the channel region.

2. The microelectronic device of claim 1, wherein, for respective ones of the transistors:
each of the first source/drain region and the second source/drain region has a generally annular horizontal cross-sectional shape; and
the channel region has an additional, generally annular horizontal cross-sectional shape.

3. The microelectronic device of claim 1, wherein, for respective ones of the transistors, the gate thereof vertically extends through the stack structure and is shared with other respective ones of the transistors.

4. The microelectronic device of claim 1, wherein, for respective ones of the transistors, the gate thereof vertically extends through the stack structure, is shared with other respective ones of the transistors, and provides a connected to a reference voltage.

5. The microelectronic device of claim 1, wherein, for respective ones of the transistors, the gate thereof vertically extends through the stack structure, is shared with other respective ones of the transistors, and is coupled to socket on a top or bottom of the stack structure.

6. The microelectronic device of claim 1, wherein the backbone member extends horizontally in a first horizontal direction and the extensions extend in a second horizontal direction that is orthogonal to the first horizontal direction.

7. The microelectronic device of claim 1, wherein the memory cells comprise resistance variable memory cells.

8. A method of forming a microelectronic device, the method comprising:
forming a stack structure comprising a vertically alternating sequence of insulative structures and other insulative structures arranged in tiers;
forming dog-bone openings horizontally between an array region of the stack structure and a staircase structure of the microelectronic device, the dog-bone openings extending into the stack structure from an uppermost surface of the stack structure, each of the dog-bone openings comprising:
a central elongated portion extending in a first horizontal direction; and
two wide end portions at opposing horizontal ends of the central elongated portion;
forming thin film transistors within the dog-bone openings and at each tier of the stack structure; and
forming local word lines within the array region of the stack structure, each local word line comprising:
a backbone member extending in a second horizontal direction orthogonal to the first horizontal direction; and
extensions extending horizontally from the backbone member in a direction parallel or collinear to the first horizontal direction.

9. The method of claim 8, wherein forming the thin film transistors comprises:
recessing portions of the other insulative structures defining horizontal boundaries of the wide end portions of the dog-bone opening to form void spaces at vertical positions of the other insulative structures; and
forming semiconductor material within the void spaces.

10. The method of claim 9, wherein forming the semiconductor material within void spaces comprises forming generally horizontally annular-shaped semiconductor structures.

11. The method of claim 9, further comprising:
recessing additional portions of the other insulative structures defining horizontal boundaries of
the central elongated portions of the dog-bone openings to form additional void spaces at
the vertical positions of the other insulative structures; and
forming a channel material within the additional void spaces.

12. The method of claim 11, further comprising:
lining the channel material with a gate insulative liner; and
forming a gate material within a gate space at least partially defined by inner side surface of the gate insulative liner.

13. The method of claim 8, wherein forming the local word lines comprises:
removing portions of the other insulative structures through pillar openings within the array region to form void spaces at vertical positions of the other insulative structures; and
forming conductive structures within the void spaces.

14. The method of claim 13, wherein forming the conductive structures comprises forming portions of the local word lines and global word lines.

15. The method of claim 13, further comprising forming memory cells within the pillar openings.

16. A microelectronic device, comprising:
a stack structure comprising:
tiers, wherein, within an array region of the stack structure, each tier respectively comprises:
a first local word line comprising a first backbone member and first extensions extending orthogonally from the first backbone member in a first direction; and
a second local word line comprising a second backbone member and second extensions extending orthogonally from the second backbone member in a second, opposite direction, wherein, at least multiple first extensions of the first local word line are each horizontally nested between second extensions of the second local word line, and wherein at least multiple second extensions of the second local word line are each horizontally nested between first extensions of the first local word line; and
memory cells formed within the array region of the stack structure, each memory cell being coupled to and horizontally between at least one first extension of a first local word line and at least one a second extension of a second local word line;
first in-tier word line decoder structures, each being coupled to a first backbone member of a respective first local word line on a horizontal side of the first backbone member opposite the first extensions, each of the first in-tier word line decoder structures comprising first thin film transistors; and
second in-tier word line decoder structures, each being coupled to a second backbone member of a respective second local word line on a horizontal side of the second backbone member opposite the second extensions, each of the second in-tier word line decoder structures comprising second thin film transistors.

17. The microelectronic device of claim 16, wherein the first thin film transistors comprise:
a first group of thin film transistors having drain structures coupled to the first backbone member of the respective first local word lines and source structures coupled to global word lines; and
a second group of thin film transistors having drain structures coupled to the first backbone member of the respective first local word lines and source structures coupled to a pillar structure providing a ground connection.

18. The microelectronic device of claim 17, wherein the global word lines are coupled to a staircase structure.

19. The microelectronic device of claim 17, wherein thin film transistors of the second group of thin film transistors that are vertically stacked relative to one another within the stack structure share a gate.

20. The microelectronic device of claim 19, wherein the gate that is shared by the vertically stacked thin film transistors of the second group of thin film transistors is coupled to a reference voltage source.
